(19) United States
(12) Patent Application Publication
(10) Pub. No.: US 2006/0134461 A1
(43) Pub. Date: Jun. 22, 2006

(54) Organometallic materials and electroluminescent devices

(76) Inventors: Shouquan Huo, Webster, NY (US); Joseph C. Deaton, Rochester, NY (US); Marina E. Kondakova, Kendall, NY (US); Christopher T. Brown, Rochester, NY (US)

Correspondence Address: Paul A. Leipold;Patent Legal Staff, Eastman Kodak Company, 343 State Street, Rochester, NY, 14650-2201, US

(21) Appl. No.: 11/016,460

(22) Filed: Dec. 17, 2004

(51) Int. Cl. H01L 51/54; H05B 33/14; C09K 11/06

(52) U.S. Cl. 428/690; 428/917; 313/504; 313/506; 313/112; 546/4; 257/E51.044; 257/102; 257/98

(57) ABSTRACT

An electroluminescent device comprises a light-emitting layer containing an organometallic compound comprising a metal and a ligand that coordinates to the metal through at least four bonds as represented by Formula (1) wherein at least one is a carbon-metal bond:
M [symbol] X)ₙ (1) wherein M represents a metal, X represents an independently selected atom, n≧4, at least one X is carbon, and all X are linked to form a multidentate ligand.

### FIELD OF THE INVENTION

This invention relates to an organic light emitting diode (OLED) electroluminescent (EL) device comprising a light-emitting layer containing an organometallic compound that can provide desirable electroluminescent properties and the organometallic compound.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100 V.

More recent organic EL devices include an organic EL element consisting of extremely thin layers (e.g. <1.0 μm) between the anode and the cathode. Herein, the term “organic EL element” encompasses the layers between the anode and cathode electrodes. Reducing the thickness lowered the resistance of the organic layer and has enabled devices that operate much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a host material doped with a guest material. Still further, there has been proposed in U.S. Pat. No. 4,769,292 a four-layer EL element comprising a hole-injecting layer (HIL), a hole-transporting layer (HTL), a light-emitting layer (LEL) and an electron transport/injection layer (ETL). These structures have resulted in improved device efficiency.

Many emitting materials that have been described as useful in an OLED device emit light from their excited singlet state by fluorescence. The excited singlet state is created when excitons formed in an OLED device transfer their energy to the excited state of the dopant. However, it is generally believed that only 25% of the excitons created in an EL device are singlet excitons. The remaining excitons are triplet, which cannot readily transfer their energy to the singlet excited state of a dopant. This results in a large loss in efficiency since 75% of the excitons are not used in the light emission process.

Triplet excitons can transfer their energy to a dopant if it has a triplet excited state that is low enough in energy. If the triplet state of the dopant is emissive it can produce light by phosphorescence. In many cases singlet excitons can also transfer their energy to lowest singlet excited state of the same dopant. The singlet excited state can often relax, by an intersystem crossing process, to the emissive triplet excited state. Thus, it is possible, by the proper choice of host and dopant, to collect energy from both the singlet and triplet excitons created in an OLED device and to produce a very efficient phosphorescent emission.

One class of useful phosphorescent materials are cyclometallated transition metal complexes having a triplet excited state. For example, fac-tris(2-phenylpyridinato-N,C^{2′})iridium(III) (Ir(ppy)₃) strongly emits green light from a triplet excited state owing to the large spin-orbit coupling of the heavy atom and to the lowest excited state which is a charge transfer state having a Laporte allowed (orbital symmetry) transition to the ground state (K. A. King, P. J. Spellane, and R. J. Watts, J. Am. Chem. Soc., 107, 1431 (1985), M. G. Colombo, T. C. Brunold, T. Reidener, H. U. Gudel, M. Fortsch, and H.-B. Burgi, Inorg. Chem., 33, 545 (1994). Small-molecule, vacuum-deposited OLEDs having high efficiency have also been demonstrated with Ir(ppy)₃ as the phosphorescent material and 4,4′-N,N′-dicarbazole-biphenyl (CBP) as the host (M. A. Baldo, S. Lamansky, P. E. Burrows, M. E. Thompson, S. R. Forrest, Appl. Phys. Lett., 75, 4 (1999), T. Tsutsui, M.-J. Yang, M. Yahiro, K. Nakamura, T. Watanabe, T. Tsuji, Y. Fukuda, T. Wakimoto, S. Miyaguchi, Jpn. J. Appl. Phys., 38, L1502 (1999)).

Another class of phosphorescent materials include compounds having interactions between atoms having d¹⁰ electron configuration, such as Au₂(dppm)Cl₂ (dppm=bis(diphenylphosphino)methane) (Y. Ma et al, Appl. Phys. Lett., 74, 1361 (1998)). Still other examples of useful phosphorescent materials include coordination complexes of the trivalent lanthanides such as Tb³⁺ and Eu³⁺ (J. Kido et al, Appl. Phys. Lett., 65, 2124 (1994)). While these latter phosphorescent compounds do not necessarily have triplets as the lowest excited states, their optical transitions do involve a change in spin state of 1 and thereby can harvest the triplet excitons in OLED devices.

Although many phosphorescent cyclometallated Ir complexes have been described as useful in an EL device, Pt-based organometallic complexes have not been examined as extensively. Some Pt phosphorescent complexes include cyclometallated Pt(II) complexes such as cis-bis(2-phenylpyridinato-N,C^{2′})platinum(II), cis-bis(2-(2′-thienyl)pyridinato-N,C^{3′}) platinum(II), cis-bis(2-(2′-thienyl)quinolinato-N,C^{5′}) platinum(II), or (2-(4,6-diflourophenyl)pyridinato-NC2′) platinum (II) acetylacetonate. However, those complexes do not give high efficiency or stability. Further, some of those complexes are not stable toward sublimation (S. Lamansky et al., WO 00/57676) and thus not suitable for vacuum-deposition to form organic films. Pt(II) porphyrin complexes such as 2,3,7,8,12,13,17,18-octaethyl-21H, 23H-porphine platinum(II) are reported in U.S. Pat. No. 6,048,630 as useful phosphorescent materials in an electroluminescent device although they did not give a very high luminance yield. Recently, C. Che, W. Lu, and M. Chan reported organometallic light-emitting materials based on (CˆNˆN) tridentate cyclometalated Pt(II) arylacetylides. (US 2002/0179885 and references cited therein). We have also disclosed organometallic light-emitting materials based on (NˆCˆN) and (CˆNˆN) tridentate cyclometallated Pt(II) complexes have been disclosed in prior filed Ser. No. 10/729,238 and Ser. No. 10/729,246, both filed Dec. 15, 2003.

It is a problem to be solved to provide new organometallic materials that will function as phosphorescent materials having improved efficiency, stability, manufacturability, and/or spectral characteristics.

### SUMMARY OF THE INVENTION

The invention provides electroluminescent device comprises a light-emitting layer containing an organometallic compound comprising a metal and a ligand that coordinates to the metal through at least four bonds as represented by Formula (1) wherein at least one is a carbon-metal bond:
M [symbol] X)ₙ (1)
wherein M represents a metal, X represents an independently selected atom, n≧4, at least one X is carbon, and all X are linked to form a multidentate ligand. The invention also provides a new organometallic complex.

The device provides new organometallic materials that will function as phosphorescent materials having improved efficiency, stability, manufacturability, and/or spectral characteristics.

### BRIEF DESCRIPTION OF THE DRAWINGS

FIG. 1 shows a schematic cross-section of a typical OLED device in which this invention can be used. Since device feature dimensions such as layer thicknesses are frequently in sub-micrometer ranges, the drawings are scaled for ease of visualization rather than dimensional accuracy.

### DETAILED DESCRIPTION OF THE INVENTION

The invention is summarized above.

The invention relates to an electroluminescent device comprising a light-emitting layer containing an organometallic compound comprising a metal and a ligand that coordinates to the metal through at least four bonds wherein at least one is a carbon-metal bond as represented by Formula (1),
M [symbol] X)ₙ (1)

Wherein M represents a metal, X represents an independently selected atom, n≧4, at least one X is carbon, and all X are linked to form a multidentate ligand.

Suitably, the organometallic compound of the invention comprises a tetradentate cyclometallating ligand. The ligand forms a tetradentate cyclometallated compound with a metal of group 10, more desirably the metal is platinum. The ligand coordinates to the metal through four bonds wherein at least one is a carbon-metal bond. The tetradentate cyclometallated compound can have either one or two carbon bonds and can be represented by the Formulas (2)-(7),

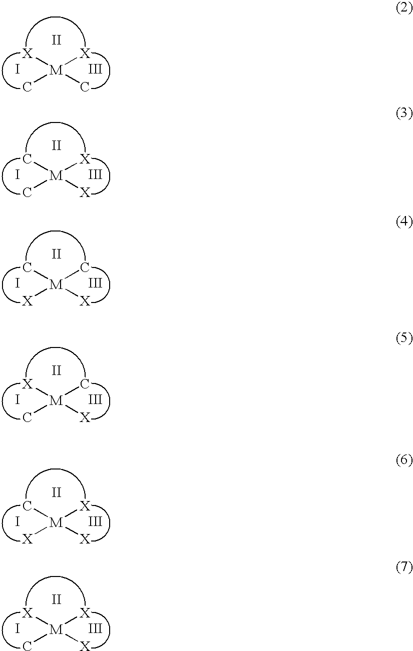

wherein,

M represents a group 10 metal; more desirably Pt;

C represents a carbon atom, more desirably an sp² carbon, conveniently a carbon of an aromatic group such as phenyl group;

X independently represents an atom selected from nitrogen, phosphorus, oxygen, or sulfur; X can coordinate to the metal through a X-metal covalent bond that is formed by loss of the hydrogen from the parent XH, examples of HX include NH, OH, and SH; X can also coordinate to the metal through a coordinative bond wherein X is a neutral atom bearing a lone pair of electrons and serving as a donor, examples of such donor include but are not limited to the followings: the nitrogen of a pyridine group or a tertiary amine group or an imine group, the phosphorus of a tertiary phosphine, the oxygen of a phosphine oxide, and the sulfur of a phosphine sulfide;

The ligand and the metal forms three metallacyclic rings I, II, and III, where the preferred size of the rings is five- or six-membered;

C and X can be part of a cyclic structure that can be further substituted, or can be part of an acyclic structure that can be further substituted.

In one suitable embodiment, the tetradentate cyclometallated organometallic compound can be incorporated into a polymer light emitting diode (PLED) device. For example, the organometallic compound can be part of the main chain of a polymer, the side chain, or intermixed with a polymer in such a device.

In one desirable embodiment, the organometallic compound can be represented by the Formulas (8)-(11)

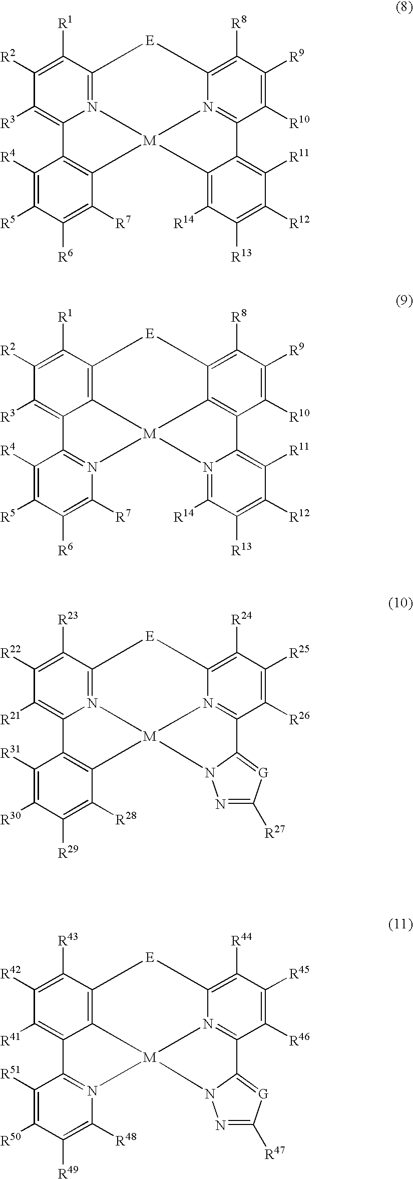

wherein:

M is Pt or Pd, preferably Pt;

R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;

R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;

R²¹-R³¹ and R⁴¹-R⁵¹ represent hydrogen or independently selected substituent. For example, R³⁷ and R⁴⁷ can be an alkyl group, more desirably perfluoroalkyl group, conveniently trifluoromethyl group; R²⁹, R³¹, R⁴¹, and R⁴³ can be a fluorine or trifluoromethyl group; R²² and R⁵⁰ can be a bulky alkyl group such as tertiary butyl group;

G represents nitrogen or carbon bearing hydrogen or a substituent;

E represents a bridging group selected from the following:

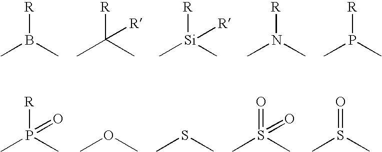

wherein R and R′ represent hydrogen or independently selected substituents, provided R and R′ may combine to form a ring group.

In one desirable embodiment, the organometallic compound is represented by Formula (12),

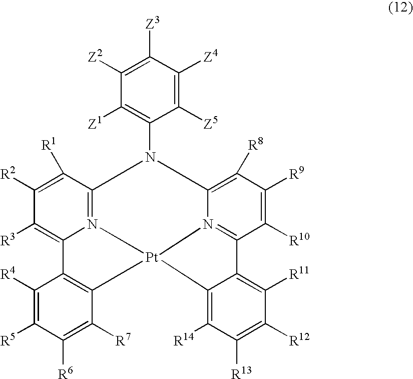

wherein,

R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;

R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;

Z¹-Z⁵ represent hydrogen or independently selected substituents, provided that Z¹ and Z², Z² and Z³, Z³ and Z⁴, as well as Z⁴ and Z⁵ may combine to form a ring group. For example, Z¹, and Z⁵ can independently represent groups such as methyl. Z¹ and Z² can combine to form a fused ring such as benzene ring groups.

Synthesis of the emitting materials useful in the invention may be accomplished by preparing an organic ligand and then using a metal to complex with the ligand and form the organometallic compound. For example, suitable tetradentate cyclometallating ligands can be prepared by the method outlined in Schemes 1-3.

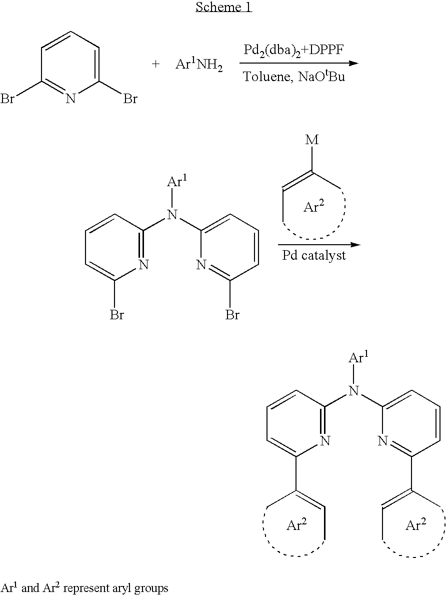

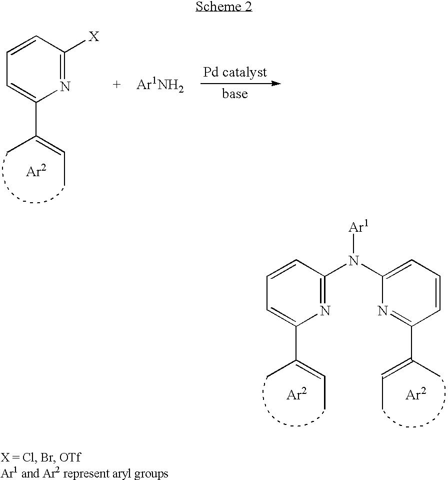

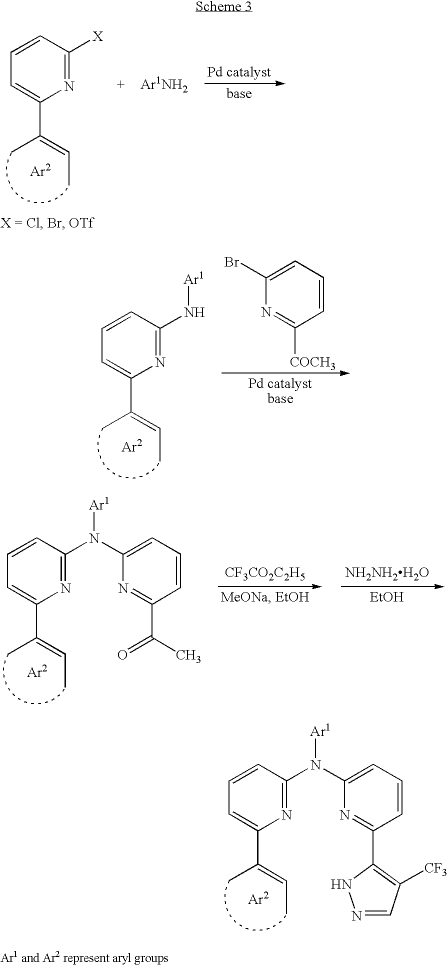

The tetradentate (CˆNˆNˆC) ligand (alternatively designated as (C,N,N,C)) shown in Scheme 1 can be prepared by two different routes. The first one involves the preparation of a precursor N,N-di-(6-bromopyrid-2-yl)arylamine by the Pd-catalyzed amination reaction (J.-S. Yang, Y.-L. Lin, and C.-S. Yang, Org. Lett. Vol. 4, 777-780, 2002) then the cross coupling of the precursor with an aryl metal such as arylboronic acids or arylzincs (Scheme 1). The second involves the Pd-catalyzed amination of an arylamine with a 2-brom-6-arylpyridine (Scheme 2). The 2-bromo-6-arylpyridine can be prepared according literature methods or by the cross coupling of 2,6-dibromopyridine with one equivalent of aryl metal such as arylzincs or arylboronic acids. The tetradentate (CˆNˆNˆN) ligand shown in Scheme 3 can be prepared by two steps of Pd-catalyzed cross coupling reactions followed by known literature procedures. It should be mentioned that both pyridine and aryl rings shown in Schemes 1-3 can bear appropriate substituents.

In Schemes 4 and 5 is shown general preparation of the organometallic compound using the tetradentate ligands prepared according to Scheme 1-3. The tetradentate ligand reacts with a platinum salt such as K₂PtCl₄ in a proper organic solvent such as glacial acetic acid to form the tetradentate cyclometallated platinum compound. A tetraakylammonium salt such as tetrabutylammonium chloride can be used as a phase transfer catalyst to accelerate the reaction.

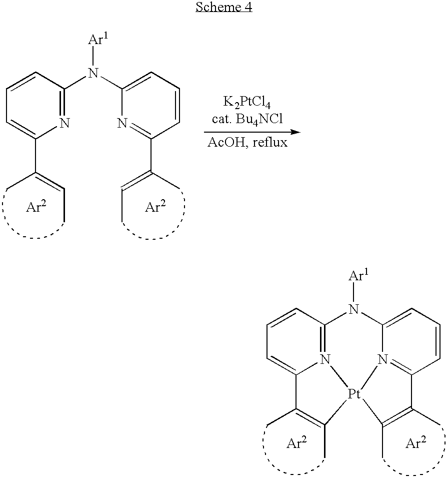

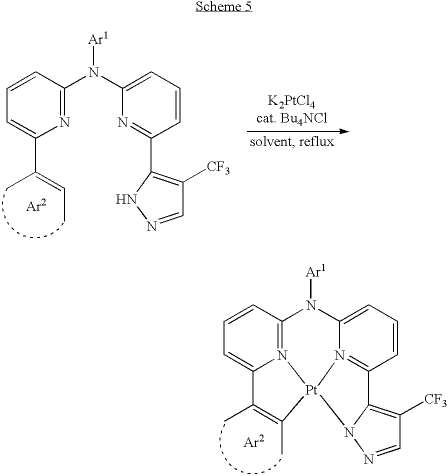

Illustrative examples of useful compounds of this invention include:

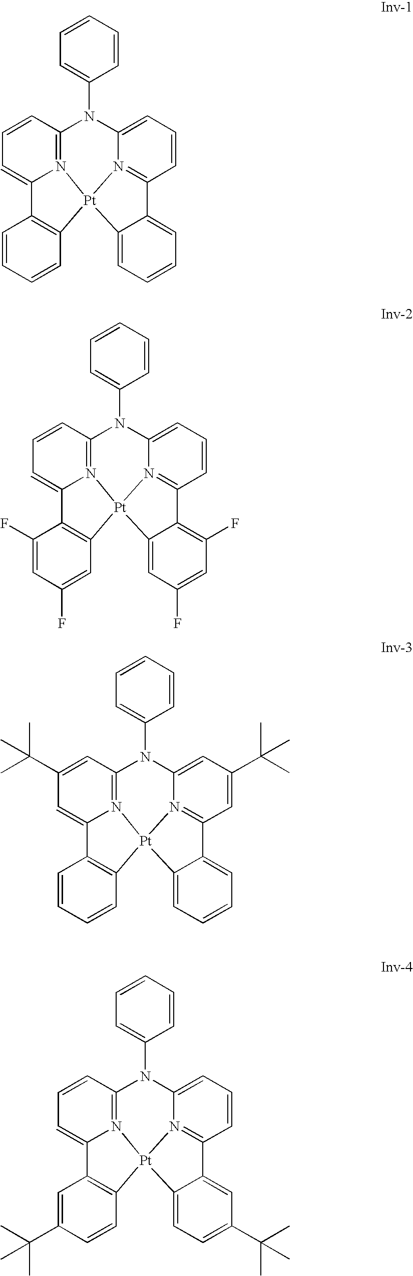

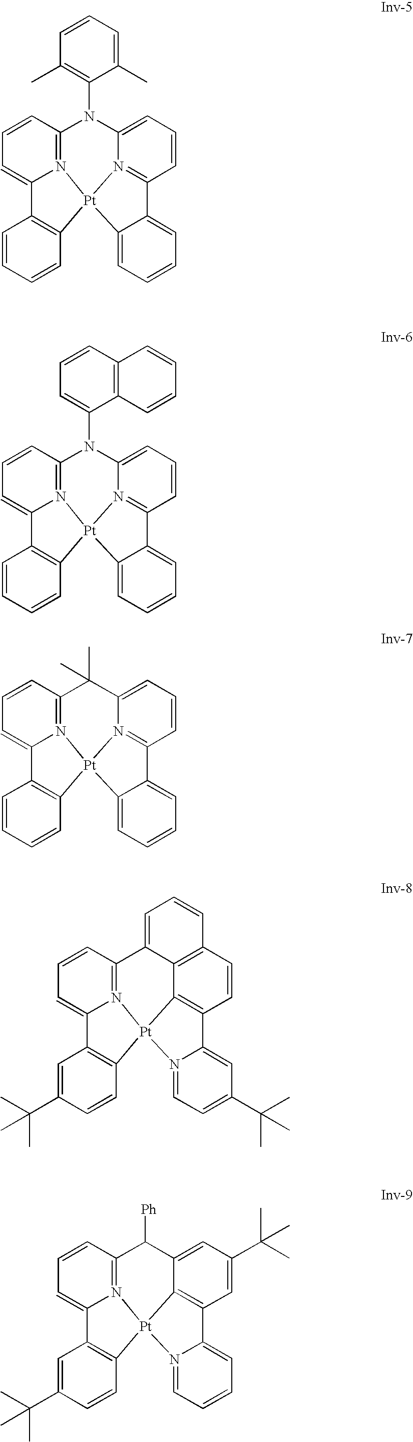

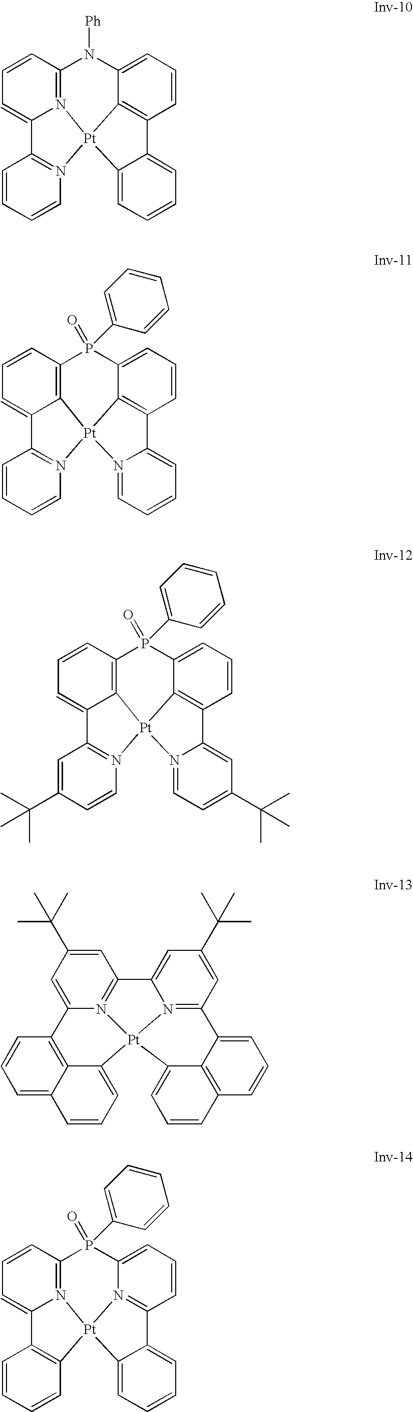

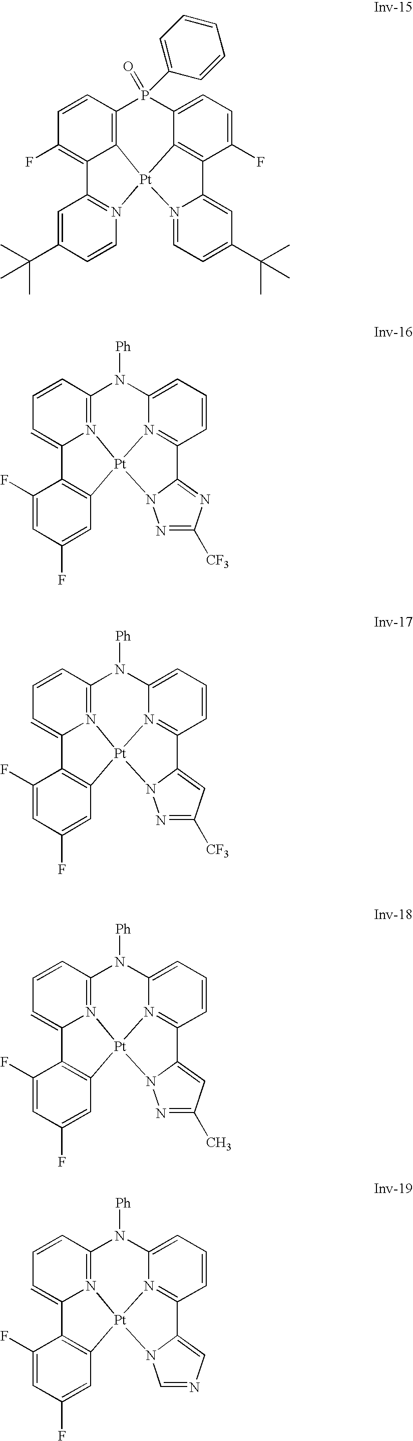

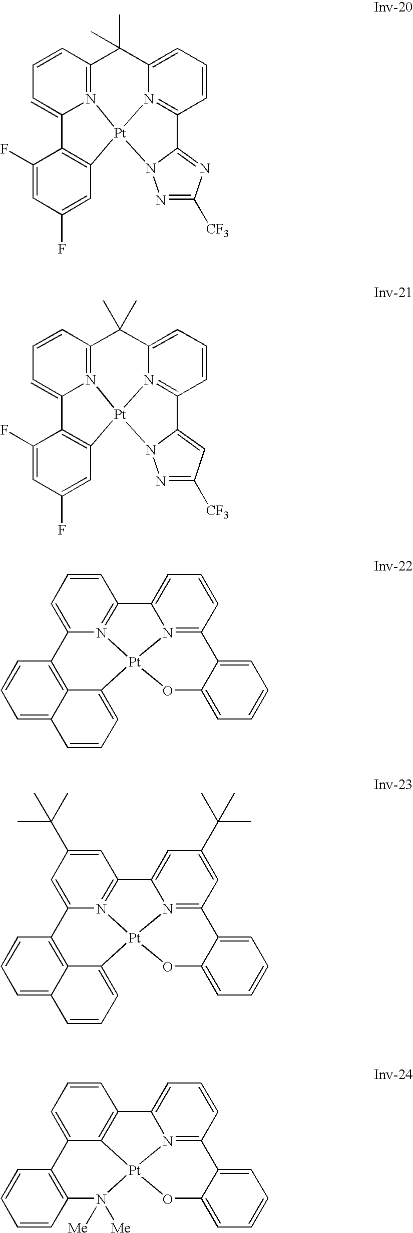

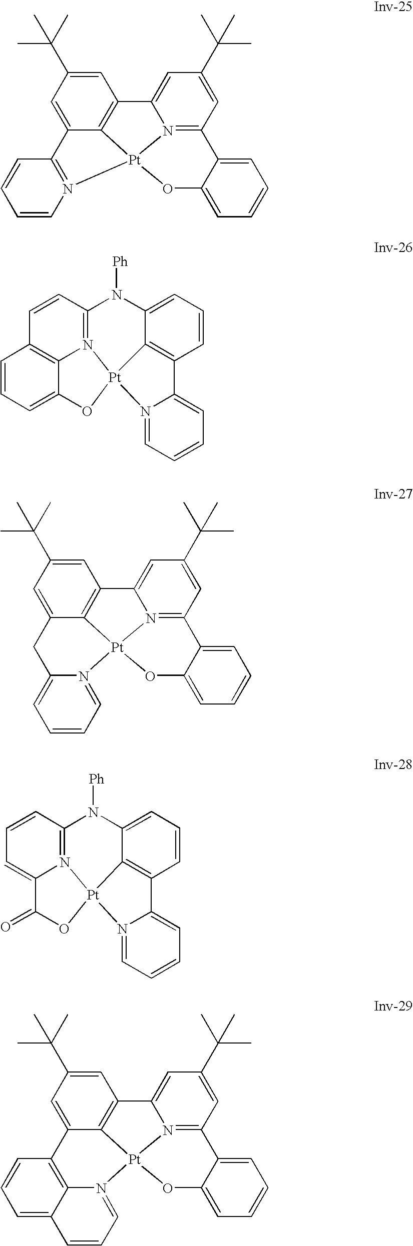

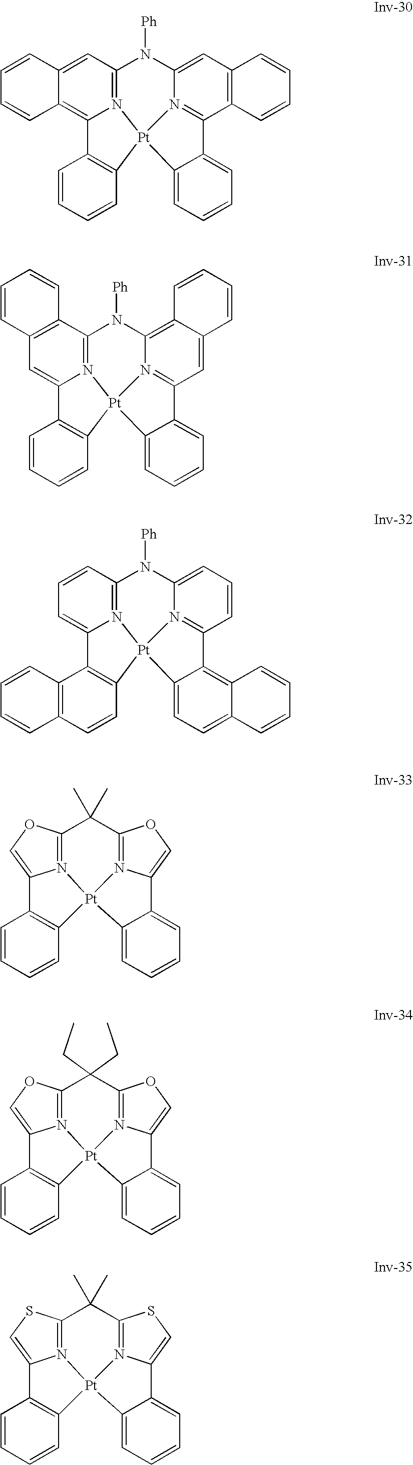

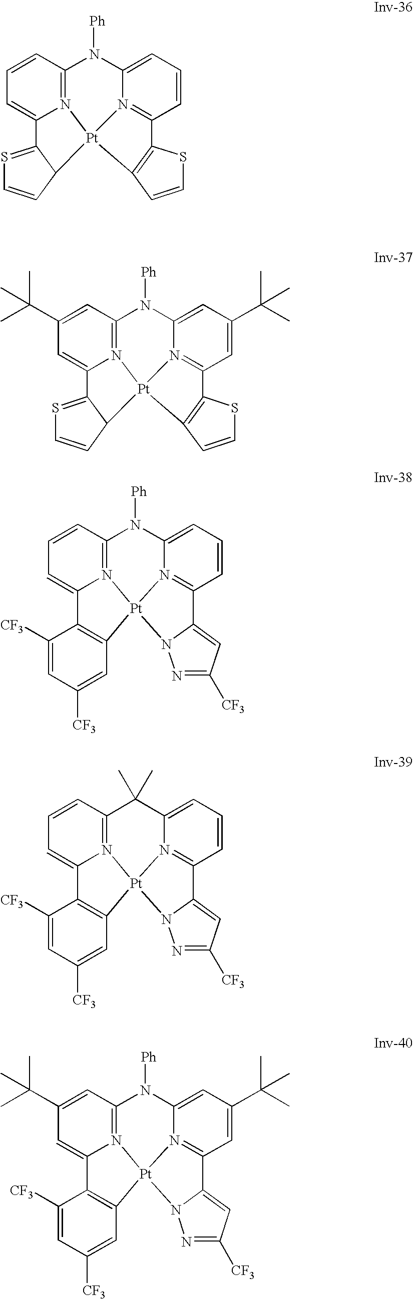

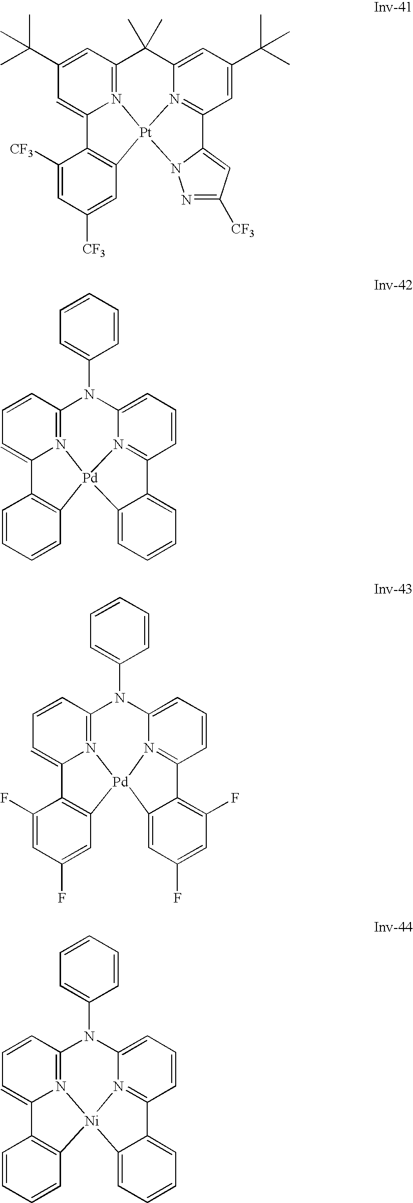

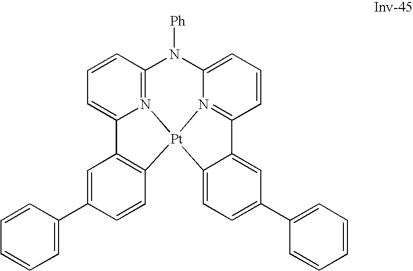

Embodiments of the invention can provide advantageous features such as operating efficiency, higher luminance, color hue, low drive voltage, and improved operating stability. Embodiments of the organometallic compounds useful in the invention can provide a wide range of hues including those useful in the emission of white light (directly or through filters to provide multicolor displays).

Unless otherwise specifically stated, use of the term “substituted” or “substituent” means any group or atom other than hydrogen. Unless otherwise specifically stated, use of the term “aromatic ring system” means a system of one ring or more than one ring fused together, where the entire ring system is aromatic. Unless otherwise specifically stated, use of the term “substituted phenyl ring” means a phenyl ring that is substituted and may be substituted to form one substituted or unsubstituted fused aromatic ring system, or more than one substituted or unsubstituted fused aromatic ring systems. Unless otherwise provided, when a group (including a compound or complex) containing a substitutable hydrogen is referred to, it is also intended to encompass not only the unsubstituted form, but also form further substituted with any substituent group, or groups as herein mentioned, including a fused ring, so long as the substituent does not destroy properties necessary for utility. Suitably, a substituent group may be halogen or may be bonded to the remainder of the molecule by an atom of carbon, silicon, oxygen, or phosphorous. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy)propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain the desired desirable properties for a specific application and can include, for example, electron-withdrawing groups, electron-donating groups, and steric groups.

General Device Architecture

The present invention can be employed in many OLED device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

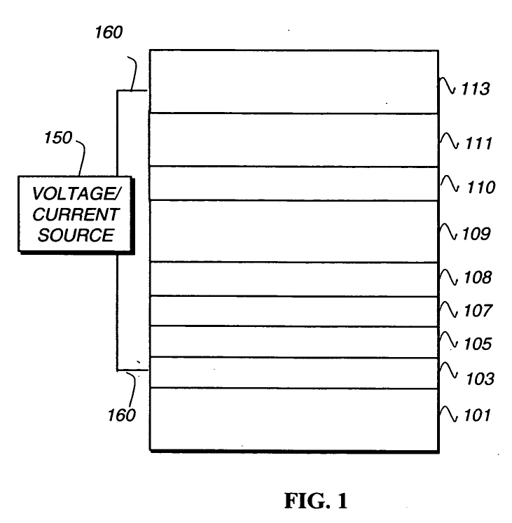

A typical structure, especially useful for of a small molecule device, is shown in FIG. 1 and is comprised of a substrate 101, an anode 103, a hole-injecting layer 105, a hole-transporting layer 107, a light-emitting layer 109, a hole- or exciton-blocking layer 110, an electron-transporting layer 111, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is desirably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate where either the cathode or anode can be in contact with the substrate. The substrate can be a complex structure comprising multiple layers of materials. This is typically the case for active matrix substrates wherein TFTs are provided below the OLED layers. It is still necessary that the substrate, at least in the emissive pixilated areas, be comprised of largely transparent materials. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support can be light transmissive, light absorbing or light reflective. Substrates for use in this case include, but are not limited to, glass, plastic, semiconductor materials, silicon, ceramics, and circuit board materials. Of course it is necessary to provide in these device configurations a light-transparent top electrode.

Anode

When the desired electroluminescent light emission (EL) is viewed through the anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful to provide a hole-injecting layer between the anode and the hole-transporting layer. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,127,004, U.S. Pat. No. 6,208,075 and U.S. Pat. No. 6,208,077, some aromatic amines, for example, m-MTDATA (4,4′,4″-tris[(3-methylphenyl)phenylamino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
N,N,N′,N′-tetraphenyl-4,4′″-diamino-1,1′:4′, 1″:4″, 1′″-quaterphenyl
Bis(4-dimethylamino-2-methylphenyl)phenylmethane
1,4-bis[2-[4-[N,N-di(p-toly)amino]phenyl]vinyl]benzene (BDTAPVB)
N,N,N′,N′-Tetra-p-tolyl-4,4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl (NPB)
4,4′-Bis[N-(1-naphthyl)-N-(2-naphthyl)amino]biphenyl (TNB)
4,4′-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4′-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
2,6-Bis[N,N-di(2-naphthyl)amino]fluorene
4,4′,4″-tris[(3-methylphenyl)phenylamino]triphenylamine (MTDATA)

4,4′-Bis[N-(3-methylphenyl)-N-phenylamino]biphenyl (TPD) Another class of useful hole-transporting materials includes polycyclic aromatic compounds as described in EP 1 009 041. Some hole-injecting materials described in EP 0 891 121 A1 and EP 1 029 909 A1, can also make useful hole-transporting materials. In addition, polymeric hole-transporting materials can be used including poly(N-vinylcarbazole) (PVK), polythiophenes, polypyrrole, polyaniline, and copolymers including poly(3,4-ethylenedioxythiophene)/poly(4-styrenesulfonate) also called PEDOT/PSS.

Light-Emitting Layer (LEL)

Suitably, the light-emitting layer of the OLED device comprises a host material and one or more guest materials for emitting light. At least one of the guest materials is suitably phosphorescent material of Formulas 1-12. The light-emitting guest material(s) is usually present in an amount less than the amount of host materials and is typically present in an amount of up to 15 wt % of the host, more typically from 0.1-10 wt % of the host. For convenience, the light-emitting guest material may be referred to as a light emitting dopant. A phosphorescent guest material may be referred to herein as a phosphorescent material, or phosphorescent dopant. The phosphorescent material of Formulas 1-12 is preferably a low molecular weight compound, but it may also be an oligomer or a polymer having a main chain or a side chain of repeating units having the moiety represented by Formulas 1-12. It may be provided as a discrete material dispersed in the host material, or it may be bonded in some way to the host material, for example, covalently bonded into a polymeric host.

Host Materials for Phosphorescent Materials

Suitable host materials should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655; WO 01/39234; WO 01/93642; WO 02/074015; WO 02/15645, and US 20020117662. Suitable hosts include certain aryl amines, triazoles, metal-chelated oxinoid compounds, indoles and carbazole compounds. Examples of desirable hosts are bis(8-quinolinolato)(4-phenylphenolato)aluminum (III) (BAlQ-7), bis(8-quinolinolato)(2,6-diphenylphenolato)aluminum (III) (BAlQ-13), 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Desirable host materials are capable of forming a continuous film.

The light emitting layer may contain more than one host material in order to improve the device's film morphology, electrical properties, light emission efficiency, and lifetime. In a preferred embodiment of the present invention, the light emitting layer contains a first co-host material that has good hole transporting properties, and a second co-host material that has good electron transporting properties.

The desirable hole transporting co-host may be any suitable hole transporting compound, such as a triarylamine or a carbazole, as long it has a triplet energy higher than that of the phosphorescent emitter to be employed.

A suitable class of hole transporting compounds for use as a co-host of the present invention are aromatic tertiary amines, by which it is understood to be compounds containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen containing group are disclosed by Brantley et al. in U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A): 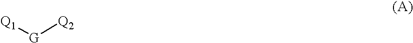
wherein Q₁ and Q₂ are independently selected aromatic tertiary amine moieties, and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 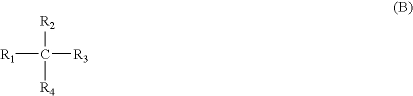
wherein

R₁ and R₂ each independently represents a hydrogen atom, an aryl group, or an alkyl group; or R₁ and R₂ together represent the atoms completing a cycloalkyl group; and

R₃ and R⁴ each independently represents an aryl group, which is in turn substituted with a diaryl substituted amino group, as indicated by structural formula (C): 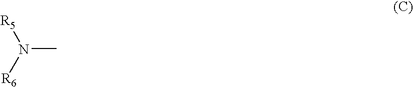
wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by formula (C), linked through an arylene group. Useful tetraaryldiamines include those represented by formula (D): 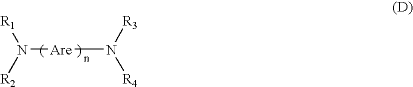
wherein each Are is an independently selected arylene group, such as a phenylene or anthracene moiety,

n is selected from 1 to 4, and

R₁-R₄ are independently selected aryl groups.

In a typical embodiment, at least one of R₁-R₄ is a polycyclic fused ring structure, e.g., a naphthalene.

The various alkyl, alkylene, aryl, and arylene moieties of the foregoing structural formulas (A), (B), (C), and (D) can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms, such as cyclopentyl, cyclohexyl, and cycloheptyl ring structures. The aryl and arylene moieties are usually phenyl and phenylene moieties.

Representative examples of the useful compounds include the following:
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(3-methylphenyl)-N-phenylamino]biphenyl (TPD);
4,4′-Bis-diphenylamino-terphenyl;
2,6,2′,6′-tetramethyl-N,N,N′,N′-tetraphenyl-benzidine.

In one suitable embodiment the hole transporting co-host comprises a material of formula (E):

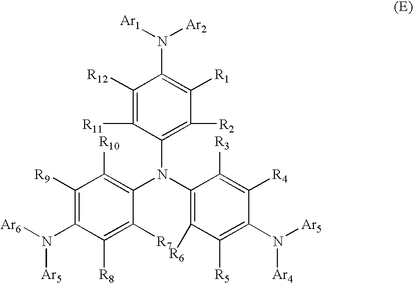

In formula (E), Ar₁-Ar₆ independently represent aromatic groups, for example, phenyl groups or tolyl groups;

R₁-R₁₂ independently represent hydrogen or independently selected substituent, for example an alkyl group containing from 1 to 4 carbon atoms, an aryl group, a substituted aryl group.

Examples of the suitable materials include, but are not limited to:
4,4′,4″-tris[(3-methylphenyl)phenylamino]triphenylamine (MTDATA);
4,4′,4″-tris(N,N-diphenyl-amino) triphenylamine (TDATA);
N,N-bis[2,5-dimethyl-4-[(3-methylphenyl)phenylamino]phenyl]-2,5-dimethyl-N′-(3-methylphenyl)-N′-phenyl-1,4-benzenediamine.

In one desirable embodiment the hole transporting co-host comprises a material of formula (F):

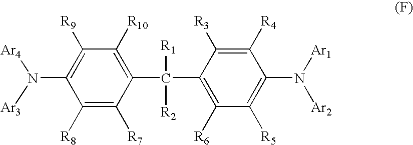

In formula (F), R₁ and R₂ represent substituents, provided that R₁ and R₂ can join to form a ring. For example, R₁ and R₂ can be methyl groups or join to form a cyclohexyl ring;

Ar₁-Ar₄ represent independently selected aromatic groups, for example phenyl groups or tolyl groups;

R₃-R₁₀ independently represent hydrogen, alkyl, substituted alkyl, aryl, substituted aryl group.

Examples of suitable materials include, but are not limited to:
1,1-Bis(4-(N,N-di-p-tolylamino)phenyl)cyclohexane (TAPC);
1,1-Bis(4-(N,N-di-p-tolylamino)phenyl)cyclopentane;
4,4′-(9H-fluoren-9-ylidene)bis[N,N-bis(4-methylphenyl)-benzenamine;
1,1-Bis(4-(N,N-di-p-tolylamino)phenyl)-4-phenylcyclohexane;
1,1-Bis(4-(N,N-di-p-tolylamino)phenyl)-4-methylcyclohexane;
1,1-Bis(4-(N,N-di-p-tolylamino)phenyl)-3-phenylpropane;
Bis[4-(N,N-diethylamino)-2-methylphenyl](4-methylpenyl)methane;
Bis[4-(N,N-diethylamino)-2-methylphenyl](4-methylphenyl)ethane;
4-(4-Diethylaminophenyl)triphenylmethane;
4,4′-Bis(4-diethylaminophenyl)diphenylmethane.

A useful class of triarylamines suitable for use as the hole transporting co-host includes carbazole derivatives such as those represented by formula (G):

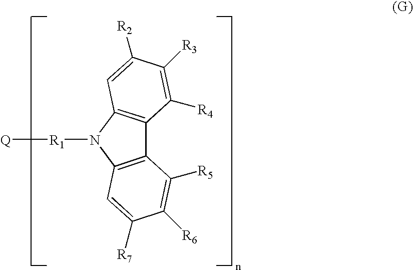

In formula (G), Q independently represents nitrogen, carbon, an aryl group, or substituted aryl group, preferably a phenyl group;

R₁ is preferably an aryl or substituted aryl group, and more preferably a phenyl group, substituted phenyl, biphenyl, substituted biphenyl group;

R₂ through R₇ are independently hydrogen, alkyl, phenyl or substituted phenyl group, aryl amine, carbazole, or substituted carbazole;

and n is selected from 1 to 4.

Another useful class of carbazoles satisfying structural formula (G) is represented by formula (H): 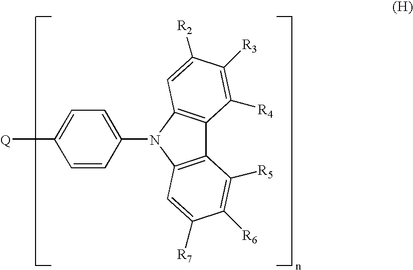
wherein n is an integer from 1 to 4;

Q is nitrogen, carbon, an aryl, or substituted aryl;

R₂ through R₇ are independently hydrogen, an alkyl group, phenyl or substituted phenyl, an aryl amine, a carbazole and substituted carbazole.

Illustrative of useful substituted carbazoles are the following:
4-(9H-carbazol-9-yl)-N,N-bis[4-(9H-carbazol-9-yl)phenyl]-benzenamine (TCTA);
4-(3-phenyl-9H-carbazol-9-yl)-N,N-bis[4(3-phenyl-9H-carbazol-9-yl)phenyl]-benzenamine;
9,9′-[5′-[4-(9H-carbazol-9-yl)phenyl][1,1′:3′,1″-terphenyl]-4,4″-diyl]bis-9H-carbazole.

In one suitable embodiment the hole transporting co-host comprises a material of formula (I):

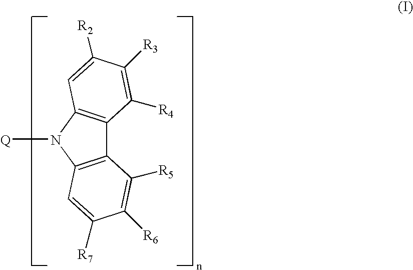

In formula I, n is selected from 1 to 4;

Q independently represents phenyl group, substituted phenyl group, biphenyl, substituted biphenyl group, aryl, or substituted aryl group;

R₁ through R₆ are independently hydrogen, alkyl, phenyl or substituted phenyl, aryl amine, carbazole, or substituted carbazole.

Examples of suitable materials are the following:
9,9′-(2,2′-dimethyl[1,1′-biphenyl]-4,4′-diyl)bis-9H-carbazole (CDBP);
9,9′-[1,1′-biphenyl]-4,4′-diylbis-9H-carbazole (CBP);
9,9′-(1,3-phenylene)bis-9H-carbazole (mCP);
9,9′-(1,4-phenylene)bis-9H-carbazole;
9,9′,9″-(1,3,5-benzenetriyl)tris-9H-carbazole;
9,9′-(1,4-phenylene)bis[N,N,N′,N′-tetraphenyl-9H-carbazole-3,6-diamine;
9-[4-(9H-carbazol-9-yl)phenyl]-N,N-diphenyl-9H-carbazol-3-amine;
9,9′-(1,4-phenylene)bis[N,N-diphenyl-9H-carbazol-3-amine;
9-[4-(9H-carbazol-9-yl)phenyl]-N,N,N′,N′-tetraphenyl-9H-carbazole-3,6-diamine.

The optimum concentration of the hole transporting co-host in a preferred embodiment of the present invention may be determined by experimentation and may be within the range 10 to 60 weight % of the total of the hole- and electron transporting co-host materials in the light emitting layer, and is often found to be in the range 15 to 30 wt. %.

The desirable electron transporting co-host may be any suitable electron transporting compound, such as benzazole, phenanthroline, 1,3,4-oxadiazole, triazole, triazine, or triarylborane, as long as it has a triplet energy that is higher than that of the phosphorescent emitter to be employed.

A preferred class of benzazoles is described by Jianmin Shi et al. in U.S. Pat. No. 5,645,948 and U.S. Pat. No. 5,766,779. Such compounds are represented by structural formula (J): 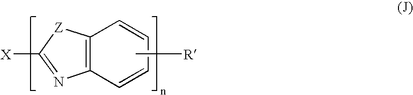
In formula (J), n is selected from 2 to 8;
Z is independently O, NR or S;
R and R′ are individually hydrogen; alkyl of from 1 to 24 carbon atoms, for example, propyl, t-butyl, heptyl, and the like; aryl or hetero-atom substituted aryl of from 5 to 20 carbon atoms, for example, phenyl and naphthyl, furyl, thienyl, pyridyl, quinolinyl and other heterocyclic systems; or halo such as chloro, fluoro; or atoms necessary to complete a fused aromatic ring; and

X is a linkage unit consisting of carbon, alkyl, aryl, substituted alkyl, or substituted aryl, which conjugately or unconjugately connects the multiple benzazoles together.

An example of a useful benzazole is 2,2′,2″-(1,3,5-phenylene)tris[1-phenyl-1H-benzimidazole] (TPBI) represented by a formula (K) shown below:

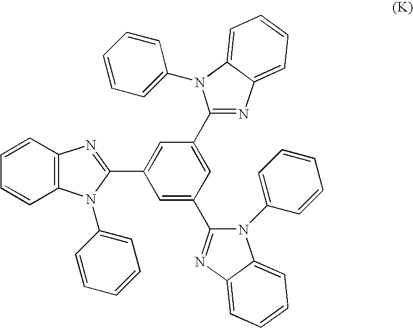

Another class of the electron transporting materials suitable for use as a co-host includes various substituted phenanthrolines as represented by formula (L):

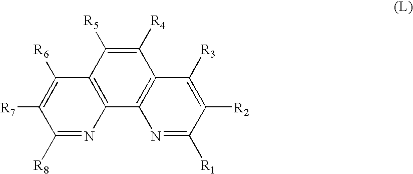

In formula (L), R₁-R₈ are independently hydrogen, alkyl group, aryl or substituted aryl group, and at least one of R₁-R₈ is aryl group or substituted aryl group.

Examples of suitable materials are 2,9-dimethyl-4,7-diphenyl-phenanthroline (BCP) (see formula (M)) and 4,7-diphenyl-1,10-phenanthroline (Bphen) (see formula (N)).

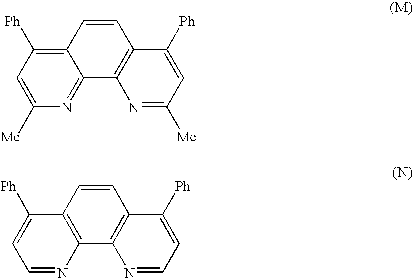

The triarylboranes that function as the electron transporting co-host in the present invention may be selected from compounds having the chemical formula (O): 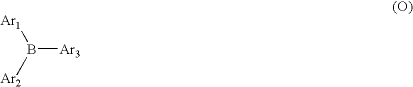
wherein

Ar₁ to Ar₃ are independently an aromatic hydrocarbocyclic group or an aromatic heterocyclic group which may have a substituent. It is preferable that compounds having the above structure are selected from formula (P): 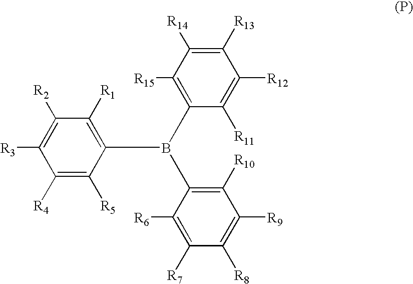
wherein R₁-R₁₅ are independently hydrogen, fluoro, cyano, trifluoromethyl, sulfonyl, alkyl, aryl or substituted aryl group.

Specific representative embodiments of the triarylboranes include:

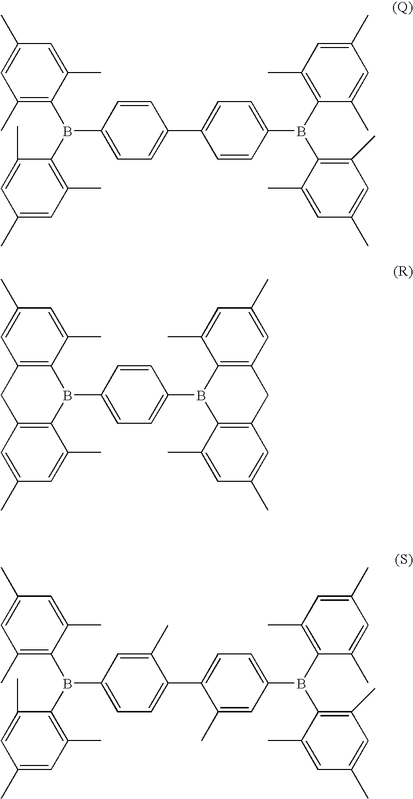

The electron transporting co-host in the present invention may be selected from substituted 1,3,4-oxadiazoles. Illustrative of the useful substituted oxadiazoles are the following:

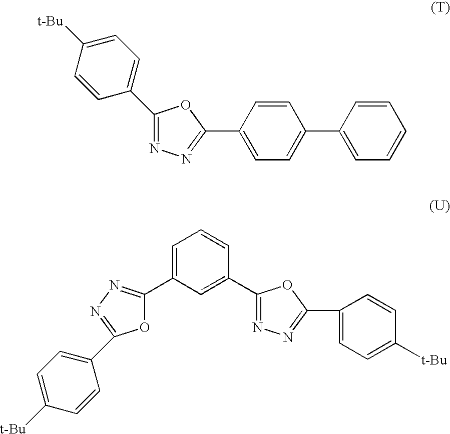

The electron transporting co-host in the present invention also may be selected from substituted 1,2,4-triazoles. An example of a useful triazole is 3-phenyl-4-(1-naphtyl)-5-phenyl-1,2,4-triazole represented by formula (V):

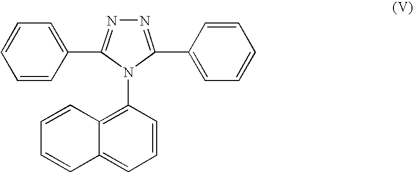

The electron transporting co-host in the present invention also may be selected from substituted 1,3,5-triazines. Examples of suitable materials are:
2,4,6-tris(diphenylamino)-1,3,5-triazine;
2,4,6-tricarbazolo-1,3,5-triazine;
2,4,6-tris(N-phenyl-2-naphthylamino)-1,3,5-triazine;
2,4,6-tris(N-phenyl-1-naphthylamino)-1,3,5-triazine;
4,4′,6,6′-tetraphenyl-2,2′-bi-1,3,5-triazine;
2,4,6-tris([1,1′:3′,1″-terphenyl]-5′-yl)-1,3,5-triazine.

The optimum concentration of the electron transporting co-host in a preferred embodiment of the present invention may be determined by experimentation and may be within the range from 40 to 90 weight %, and is often found to be in the range from 70 to 85 weight %.

Phosphorescent Materials

Phosphorescent materials of Formulas 1-12 may be used singly or in combination with other phosphorescent materials, either in the same or different layers. Some other phosphorescent materials are described in WO 00/57676, WO 00/70655, WO 01/41512, WO 02/15645, US 2003/0017361, WO 01/93642, WO 01/39234, U.S. Pat. No. 6,458,475, WO 02/071813, U.S. Pat. No. 6,573,651, US 2002/0197511, WO 02/074015, U.S. Pat. No. 6,451,455, US 2003/0072964, US 2003/0068528, U.S. Pat. No. 6,413,656, U.S. Pat. No. 6,515,298, U.S. Pat. No. 6,451,415, U.S. Pat. No. 6,097,147, US 2003/0124381, US 2003/0059646, US 2003/0054198, EP 1 239 526, EP 1 238 981, EP 1 244 155, US 2002/0100906, US 2003/0068526, US 2003/0068535, JP 2003073387, JP 2003073388, US 2003/0141809, US 2003/0040627, JP 2003059667, JP 2003073665, and US 2002/0121638.

The emission wavelengths of cyclometallated Ir(III) complexes of the type IrL₃ and IrL₂L′, such as the green-emitting fac-tris(2-phenylpyridinato-N,C^{2′})Iridium(III) and bis(2-phenylpyridinato-N,C^{2′})Iridium(III)(acetylacetonate) may be shifted by substitution of electron donating or withdrawing groups at appropriate positions on the cyclometallating ligand L, or by choice of different heterocycles for the cyclometallating ligand L. The emission wavelengths may also be shifted by choice of the ancillary ligand L′. Examples of red emitters are the bis(2-(2′-benzothienyl)pyridinato-N,C^{3′})Iridium(III)(acetylacetonate) and tris(2-phenylisoquinolinato-N,C)Iridium(III). A blue-emitting example is bis(2-(4,6-diflourophenyl)-pyridinato-N,C^{2′})Iridium(III)(picolinate).

Red electrophosphorescence has been reported, using bis(2-(2′-benzo[4,5-a]thienyl)pyridinato-N, C³) iridium (acetylacetonate) [Btp₂Ir(acac)] as the phosphorescent material (Adachi, C., Lamansky, S., Baldo, M. A., Kwong, R. C., Thompson, M. E., and Forrest, S. R., App. Phys. Lett., 78, 1622-1624 (2001).

Other important phosphorescent materials include cyclometallated Pt(II) complexes such as cis-bis(2-phenylpyridinato-N,C^{2′})platinum(II), cis-bis(2-(2′-thienyl)pyridinato-N,C^{3′}) platinum(II), cis-bis(2-(2′-thienyl)quinolinato-N,C^{5′}) platinum(II), or (2-(4,6-diflourophenyl)pyridinato-NC2′) platinum (II) acetylacetonate. Pt(II) porphyrin complexes such as 2,3,7,8,12,13,17,18-octaethyl-21H, 23H-porphine platinum(II) are also useful phosphorescent materials.

Still other examples of useful phosphorescent materials include coordination complexes of the trivalent lanthanides such as Tb³⁺ and Eu³⁺ (J. Kido et al, Appl. Phys. Lett., 65, 2124 (1994))

Blocking Layers

In addition to suitable hosts, an OLED device employing a phosphorescent material often requires at least one exciton blocking layer 108 and/or a hole blocking layer 110 to help confine the excitons or electron-hole recombination centers to the light-emitting layer comprising the host and phosphorescent material. In one embodiment, such a blocking layer would be placed between the electron-transporting layer and the light-emitting layer—see FIG. 1, layer 110. In this case, the ionization potential of the blocking layer should be such that there is an energy barrier for hole migration from the host into the electron-transporting layer, while the electron affinity should be such that electrons pass more readily from the electron-transporting layer into the light-emitting layer comprising host and phosphorescent material. It is further desired, but not absolutely required, that the triplet energy of the blocking material be greater than that of the phosphorescent material. Suitable hole-blocking materials are described in WO 00/70655 and WO 01/93642. Two examples of useful materials are bathocuproine (BCP) and bis(2-methyl-8-quinolinolato)(4-phenylphenolato)Aluminum(III) (BAlQ).

A preferred embodiment of an OLED device employing a phosphorescent emitter according to the present invention may include at least one exciton blocking layer, 108 (FIG. 1), placed adjacent the light emitting layer 109 on the anode side, to help confine triplet excitons to the light emitting layer comprising a host or co-hosts and a phosphorescent emitter. In order that the exciton blocking layer be capable of confining triplet excitons, the material or materials of this layer should have triplet energies that exceed that of the phosphorescent emitter. Otherwise, if the triplet energy level of any material in the layer adjacent the light emitting layer is lower than that of the phosphorescent emitter, often that material will quench excited states in the light emitting layer, decreasing device luminous efficiency. In some cases it is also desirable that the exciton blocking layer also help to confine electron-hole recombination events to the light emitting layer by blocking the escape of electrons from the light emitting layer into the exciton blocking layer. In order that the exciton blocking layer have this electron blocking property, the material or materials of this layer should have solid-state electron affinities that exceed the electron affinities of the materials in the light emitting layer by at least 0.1 eV and preferably by at least 0.2 eV.

Triplet energy is conveniently measured by any of several means, as discussed for instance in S. L. Murov, I. Carmichael, and G. L. Hug, Handbook of Photochemistry, 2nd ed. (Marcel Dekker, New York, 1993).

The triplet state of a compound can also be calculated. The triplet state energy for a molecule is obtained as the difference between the ground state energy (E(gs)) of the molecule and the energy of the lowest triplet state (E(ts)) of the molecule, both given in eV. These energies are obtained using the B3LYP method as implemented in the Gaussian 98 (Gaussian, Inc., Pittsburgh, Pa.) computer program. The basis set for use with the B3LYP method is defined as follows: MIDI! for all atoms for which MIDI! is defined, 6-31G* for all atoms defined in 6-31G* but not in MIDI!, and either the LACV3P or the LANL2DZ basis set and pseudopotential for atoms not defined in MIDI! or 6-31G*, with LACV3P being the preferred method. For any remaining atoms, any published basis set and pseudopotential may be used. MIDI!, 6-31G* and LANL2DZ are used as implemented in the Gaussian98 computer code and LACV3P is used as implemented in the Jaguar 4.1 (Schrodinger, Inc., Portland Oreg.) computer code. The energy of each state is computed at the minimum-energy geometry for that state. The difference in energy between the two states is further modified by equation (1) to give the triplet state energy (E(t)):
E(t)=0.84*(E(ts)−E(gs))+0.35 (eq. 1).

For polymeric or oligomeric materials, it is sufficient to compute the triplet energy over a monomer or oligomer of sufficient size so that additional units do not substantially change the computed triplet energy.

The calculated values for the triplet state energy of a given compound may typically show some deviation from the experimental values. Thus, the calculations should be used only as a rough guide in the selection of appropriate materials.

The exciton blocking layer can be between 1 and 500 nm thick and suitably between 10 and 300 nm thick. Thicknesses in this range are relatively easy to control in manufacturing.

In addition to having high triplet energy, the exciton blocking layer 108 must be capable of transporting holes to the light emitting layer 109. A hole transporting material deposited in said exciton blocking layer between the anode and the light emitting layer may be the same or different from a hole transporting compound described previously to be used as a co-host according to a preferred embodiment of the invention provided that the triplet energy of the exciton blocking material is greater than that of the phosphorescent emitter. The hole transporting material deposited in said exciton blocking layer may be selected from the same set of hole transporting materials previously described for use as hole-transporting co-hosts. Additional materials that may be used as exciton blocking layer 108 that are metal complexes such as fac-tris(1-phenylpyrazolato-N,C2)iridium(III) (Irppz) are disclosed in US 20030175553. The exciton blocking layer may include more than one compound, deposited as a blend or divided into separate layers.

Electron-Transporting Layer (ETL)

Preferred thin film-forming materials for use in forming the electron-transporting layer of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with an organic layer (e.g., an electron transporting layer (ETL)) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. An ETL material doped with an alkali metal, for example, Li-doped Alq, as disclosed in U.S. Pat. No. 6,013,384, is another example of a useful EIL. Other useful cathode material sets include, but are not limited to, those disclosed in U.S. Pat. Nos. 5,059,861, 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by any suitable methods such as evaporation, sputtering, or chemical vapor deposition. When needed, patterning can be achieved through many well known methods including, but not limited to, through-mask deposition, integral shadow masking as described in U.S. Pat. No. 5,276,380 and EP 0.732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. No. 5,683,823, U.S. Pat. No. 5,503,910, U.S. Pat. No. 5,405,709, and U.S. Pat. No. 5,283,182, US 20020186214, US 20020025419, US 20040009367, and US 6627333.

Additional layers such as exciton, electron and hole-blocking layers as taught in the art may be employed in devices of this invention. Hole-blocking layers are commonly used to improve efficiency of phosphorescent emitter devices, for example, as in US 20020015859, WO 00/70655A2, WO 01/93642A1, US 20030068528 and US 20030175553 A1.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimation “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimation boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357) and inkjet method (U.S. Pat. No. 6,066,357).

Encapsulation

Most OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low melting temperature glass. Commonly, a getter or desiccant is also provided within the sealed space. Useful getters and desiccants include, alkali and alkaline metals, alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters in functional relationship with the light emitting areas of the display. Filters, polarizers, and anti-glare or anti-reflection coatings can also be provided over a cover or as part of a cover.

The OLED device may have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

### EXAMPLES

### Synthetic Example 1

Synthesis of Organometallic Compound Inv-(1)

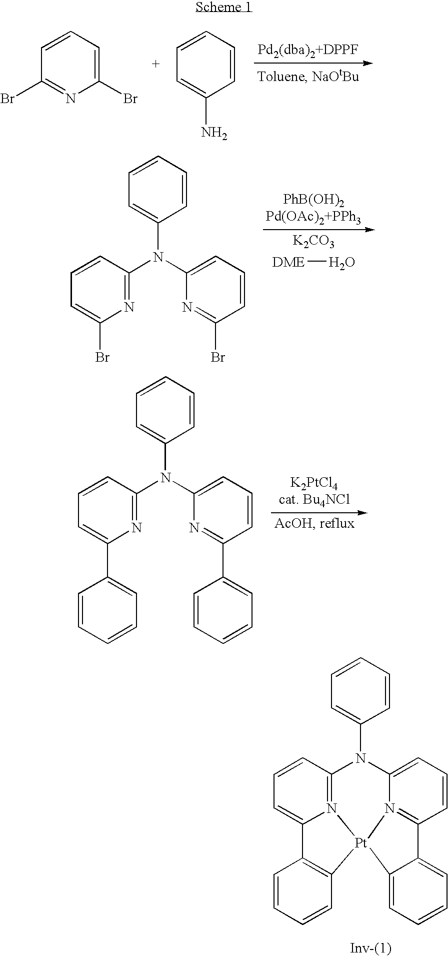

Synthesis of N,N-di-(6-bromopyrid-2-yl)aniline: A mixture of 2,6-dibromopyridine (11.85 g, 50 mmol), sodium tert-butoxide (4.8 g, 50 mmol), Pd₂(dba)₃ (366 mg, 0.4 mmol), DPPF (1,1′-bis(diphenylphosphino)ferrocene) (443 mg, 0.8 mmol), and aniline (1.8 mL, 20 mmol) in anhydrous toluene (150 mL) was stilled at 80-90° C. for 22 h. After cooling to room temperature, the mixture was poured into water and extracted with ethyl acetate. After usual workup, the crude material was purified by chromatography on silica gel with dichloromethane-heptane as an eluent, 4.83 g, 60%, N,N-di-(6-bromopyrid-2-yl)aniline, the structure of the compound was confirmed by the mass spectrum, MS m/z calcd 402.9; found: 404, 406, 408 (1:2:1) (M+1).

Synthesis of N,N-di-(6-phenylpyrid-2-yl)aniline: N,N-di-(6-bromopyrid-2-yl)aniline (2.44 g, 6 mmol), was dissolved in 35 mL of DME (dimethoxyethane). An aqueous solution of K₂CO₃ (2 M, 30 mL) was added. The mixture was degassed and triphenylphosphine (314 mg, 1.2 mmol), Pd(OAc)₂ (67 mg, 0.3 mmol), and phenylboronic acid (2.18 g, 18 mmol) were added. The mixture was refluxed under N₂ for 6 h. After usual workup, the crude product was purified by chromatography on silica gel with dichloromethane-heptane (4:1) as an eluent and recrystallization from heptane-dichloromethane to give white fine needles, N,N-di-(6-phenylpyrid-2-yl)aniline, 1.66 g, 69%. The structure of the compound was confirmed by mass spectrum, MS m/z calcd 399.2; found 400.3 (M+1).

Synthesis of organometallic compound Inv-(1): To a mixture of N,N-di-(6-phenylpyrid-2-yl)aniline (0.4 g, 1 mmol) and K₂PtCl₄ (0.42 g, 1 mmol) in glacial acetic acid (60 mL) was added tetrabutylammonium chloride (0.03 g, 0.1 mmol). The mixture was refluxed for 46 h and cooling to room temperature. The precipitates were collected by filtration and washed with water, methanol, and ether. The crude material was purified by chromatography on silica gel with dichloromethane as an eluent. The front yellow band was collected and evaporated to provide 0.47 g yellow crystals, 79%. The structure of the compound was confirmed by mass spectrum and X-ray crystal structure analysis. MS m/z calcd 592.1; found 592.1, 593.1, 594.1.

### Synthetic Example 2

Synthesis of Organometallic Compound Inv-(2)

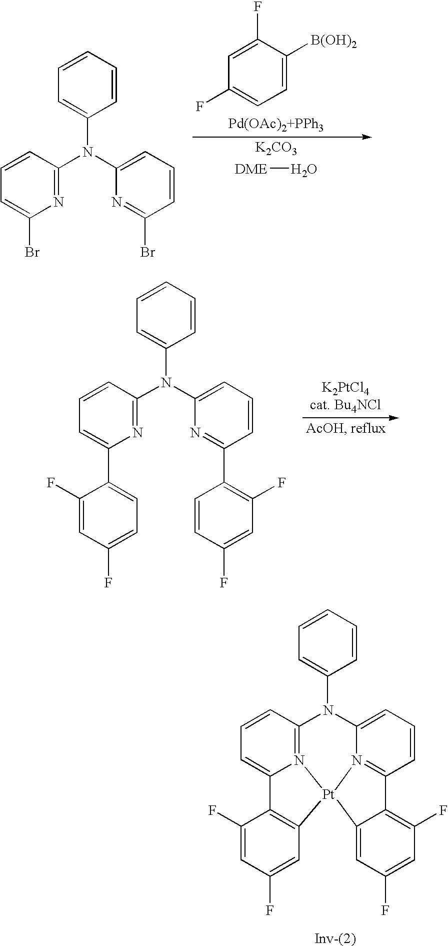

Synthesis of of N,N-di-(6-(2,4-difluorophenyl)pyrid-2-yl)aniline: A mixture of N,N-di-(6-bromopyrid-2-yl)aniline (2.36 g, 5.83 mmol), 2,4-difluorophenylboronic acid (2.76 g, 17.5 mmol), an aqueous solution of K₂CO₃ (2 M, 30 mL), and DME (dimethoxyethane, 35 mL) was degassed. Triphenylphosphine (314 mg, 1.2 mmol) and Pd(OAc)₂ (67 mg, 0.3 mmol) were added and the mixture was refluxed under N₂ for 3 h. After usual workup, the crude product was purified by chromatography on silica gel with dichloromethane-heptane (1:1) as an eluent and recrystallization from heptane to give a white solid, N,N-di-(6-(2,4-difluorophenyl)pyrid-2-yl)aniline, 2.07 g, 75%. The structure of the compound was confirmed by mass spectrum, MS m/z calcd 471.1; found 472.2 (M+1).

Synthesis of organometallic compound Inv-(2): A mixture of N,N-di-(6-(2,4-difluorophenyl)pyrid-2-yl)aniline (0.47 g, 1 mmol), tetrabutylammonium chloride (few crystals), and K₂PtCl₄ (0.42 g, 1 mmol) in glacial acetic acid (60 mL) was refluxed for 22 h. After cooling to room temperature, the precipitates were collected by filtration and washed with water and methanol and dried in air, 0.47 g greenish yellow crystalline material, 66%. The structure of the compound was confirmed by mass spectrum. MS m/z calcd 664.1; found 664.1, 665.1, 666.1 (M).

### Device Example 3 to 6

An EL device (Example 3) satisfying the requirements of the invention was constructed in the following manner:
1. A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃.
3. A hole-transporting layer (HTL) of N,N′-di-1-naphthyl-N,N′-diphenyl-4,4′-diaminobiphenyl (NPB) having a thickness of 75 nm was then evaporated from a tantalum boat.
4. A 35 nm light-emitting layer (LEL) of 4,4′-N,N′-dicarbazole-biphenyl (CBP) and organometallic compound (Inv-1) (2% doped) were then deposited onto the hole-transporting layer. These materials were also evaporated from tantalum boats.
5. A hole-blocking layer of bis(2-methyl-quinolinolate)(4-phenylphenolate) (Al(Balq)) having a thickness of 10 nm was then evaporated from a tantalum boat.
6. A 40 nm electron-transporting layer (ETL) of tris(8-quinolinolato)aluminum (III) (AlQ₃) was then deposited onto the light-emitting layer. This material was also evaporated from a tantalum boat.
7. On top of the AlQ₃ layer was deposited a 220 nm cathode formed of a 10:1 volume ratio of Mg and Ag.

The above sequence completed the deposition of the EL device. The device was then hermetically packaged in a dry glove box for protection against ambient environment.

Examples 4, 5, and 6 were fabricated in an identical manner to Example 3 except emitter Inv-1 was used at levels indicated in Table 1. The cells thus formed were tested for luminance and color at an operating current of 20 mA/cm² and the results are reported in Table 1 in the form of luminance, efficiency, life time, and CIE (Commission Internationale de L'Eclairage) coordinates.

TABLE 1
Evaluation Results for EL devices.

| | | | Effi- | | | | |
|---|---|---|---|---|---|---|---|
| Exam- | Inv-1 | Luminance | ciency | | | T_{1/2} | |
| ple | (%) | (cd/m²) | W/A | CIEx | CIEy | (h) | Type |
| 3 | 2 | 910 | 0.034 | 0.289 | 0.534 | 79 | Invention |
| 4 | 4 | 1329 | 0.047 | 0.313 | 0.579 | 64 | Invention |
| 5 | 6 | 1401 | 0.05 | 0.324 | 0.584 | 51 | Invention |
| 6 | 8 | 1264 | 0.046 | 0.334 | 0.583 | 33 | Invention |

### Device Comparative Example 7 to 9

An EL device, Example 7, was constructed in the same manner as Example 3 described above, except Com-1 was used in place of Inv-1. Examples 8 and 9 were prepared in the same manner as Example 7, except emitter Com-1 was used at the level indicated in Table 2. The cells thus formed were tested for luminance and color at an operating current of 20 mA/cm² and the results are reported in Table 1 in the form of luminance, efficiency, life time, and CIE (Commission Internationale de L'Eclairage) coordinates.

TABLE 2
Evaluation Results for EL devices.

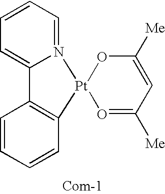

| | Com- | Lumi- | | | | | |
|---|---|---|---|---|---|---|---|
| Ex- | 1 | ance | Efficiency | | | T_{1/2} | |
| ample | (%) | (cd/m²) | (W/A) | CIEx | CIEy | (h) | Type |
| 7 | 2 | 424 | 0.019 | 0.249 | 0.457 | 1 | Comparison |
| 8 | 4 | 595 | 0.025 | 0.296 | 0.489 | 1 | Comparison |
| 9 | 6 | 711 | 0.030 | 0.330 | 0.498 | 1 | Comparison |

As can be seen from Tables 1 and 2, the invention device examples demonstrated a superior green color and higher luminance relative to the comparative device with the comparative phosphorescent organometallic material. Further, the operational stability of the invention examples is much higher than that of the device incorporating the comparative emitting material.

Another comparative compound, cis-bis(2-phenylpyridinato-N,C^{2′})platinum(II) (Com-2), however, is not suitable for OLED devices, since the emission of the compound at room temperature was so weak to be hardly detectable and the compound is very photosensitive (M. Maestri, D. Sandrini, V. Balzani, L. Chassot, P. Jolliet, and A. von Zelewsky, Chem. Phys. Lett. 122, 375-379, 1985). Further, another relevant compound cis-bis(2-(2′-thienyl)pyridinato-N,C^{3′}) platinum(II) (Com-3) did emit light at room temperature but was not stable toward sublimation or vacuum deposition (S. Lamansky et al, WO 00/57676).

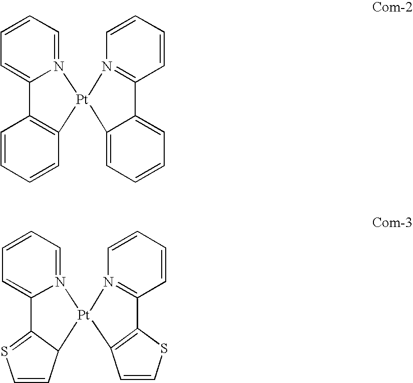

Suitable host materials and device structures that may be used in accord with the invention were further explored by fabricating devices 10,11,12, and 13 below.

### Device Examples 10-11:

An EL device (Device 10) satisfying the requirements of the invention was constructed in the following manner:
1. A glass substrate, coated with an approximately 85 nm layer of indium-tin oxide (ITO) as the anode, was sequentially ultrasonicated in a commercial detergent, rinsed in deionized water, degreased in toluene vapor and exposed to oxygen plasma for about 1 minute.
2. Over the ITO was deposited a 1 nm fluorocarbon (CFₓ) hole injecting layer (HIL) by plasma-assisted deposition of CHF₃.
3. A hole transporting layer (HTL) of N,N′-di-1-naphthyl-N,N′-diphenyl-4,4′-diaminobiphenyl (NPB) having a thickness of 65 nm was then evaporated from a resistively heated tantalum boat.
4. An exciton blocking layer (EBL) of 4,4′,4″-tris(carbazolyl)-triphenylamine (TCTA) having a thickness of 10 nm was then evaporated from a resistively heated tantalum boat.
5. A 35 nm light emitting layer (LEL) consisting of a mixture of 2,2′,2″-(1,3,5-phenylene)tris[1-phenyl-1H-benzimidazole] (TPBI) as the electron transporting co-host, TCTA as the hole transporting co-host present at a concentration of 30 wt. % of the total of the co-host materials in the LEL, and Inv-1 as a phosphorescent emitter at a concentration of 4 wt. % relative to the total of the co-host materials was then deposited onto the exciton blocking layer. These materials were also evaporated from tantalum boats.
6. A hole blocking layer (HBL) of 2,2′,2″-(1,3,5-phenylene)tris[1-phenyl-1H-benzimidazole] (TPBI) having a thickness of 10 nm was then evaporated from another tantalum boat.
7. A 40 nm electron transporting layer (ETL) of tris(8-quinolinolato) aluminum (III) (Alq) was then deposited onto the light emitting layer. This material was also evaporated from a tantalum boat.
8. On top of the Alq layer was deposited a 220 nm cathode formed of a 10:1 volume ratio of Mg and Ag.

The above sequence completed the deposition of the EL device. Therefore, Device 10 has the following structure of layers: ITO| CFₓ (1 nm)|NBP (65 nm)|TCTA (10 nm)|(TPBI+30 wt. % TCTA)+4 wt. % Inv-1 (35 nm)|TPBI (10 nm)|Alq (40 nm)|Mg:Ag (220 nm). The device, together with a desiccant, was then hermetically packaged in a dry glove box for protection against ambient environment.

An EL device (Device 11) was fabricated in an identical manner to Device 10 except TCTA was not included in the LEL and TPBI was used as the neat host for Inv-1. As a result, Device 11 has the following structure of layers: ITO|CFₓ (1 nm)|NBP (65 nm)|TCTA(10 nm)|TPBI+4 wt. % Inv-1 (35 nm)|TPBI (10 nm)|Alq (40 nm)|Mg:Ag (220 nm).

The cells thus formed were tested for efficiency and color at an operating current density of 1 mA/cm² and the results are reported in Table 3 in the form of luminance yield and CIE (Commission Internationale de l'Eclairage) coordinates.

TABLE 3
Evaluation Results for EL Devices 10 and 11.

| | Luminance | | | |
|---|---|---|---|---|
| | Yield | Voltage | | |
| Device | (cd/A) | (V) | CIEx | CIEy |
| 10 | 45.5 | 5.92 | 0.32 | 0.62 |
| 11 | 10.4 | 7.36 | 0.33 | 0.61 |

While Device 11 having neat TPBI as host for the phosphorescent emitter Inv-1 satisfies the requirements of the invention, it can be seen from Table 3 that Device 10 incorporating TPBI and TCTA materials as co-hosts provided even higher luminous yield and lower drive voltage.

### Device Examples 12-13:

A EL device (Device 12) satisfying the requirements of the invention was fabricated in an identical manner to Device 10 except that 4,4′,4″-tris[(3-methylphenyl)phenylamino]triphenylamine (MTDATA) was used in place of TCTA in the LEL. Device 12 has the following structure of layers: ITO|CFₓ (1 nm)|NBP (65 nm)|TCTA (10 nm)|(TPBI+30 wt. % MTDATA)+4 wt. % Inv-1 (35 nm)|TPBI (10 nm)|Alq (40 mm)|Mg:Ag (220 nm).

An EL device (Device 13) was fabricated in an identical manner to Device 12 except MTDATA was not included in the LEL and TPBI was used as a neat host for Inv-1. Device 13 thus has the following structure of layers: ITO|CFₓ (1 nm)|NBP (65 nm)|TCTA (10 mm)|TPBI+4 wt. % Inv-1 (35 nm)|TPBI (10 nm)|Alq (40 nm)|Mg:Ag (220 nm).

These devices were operated at a constant current density of 1 mA/cm² and voltage and luminance properties were measured. The results are shown in Table 4.

TABLE 4

| | Luminance | | | |
|---|---|---|---|---|
| | Yield | Voltage | | |
| Device | (cd/A) | (V) | CIEx | CIEy |
| 12 | 41.1 | 6.47 | 0.34 | 0.61 |
| 13 | 10.2 | 7.38 | 0.34 | 0.61 |

While Device 13 having neat TPBI as host for the phosphorescent emitter Inv-1 satisfies the requirements of the invention, it can be seen from Table 4 that Device 12 incorporating TPBI and MTDATA materials as co-hosts provides even higher luminous yield and lower drive voltage.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS LIST

101 Substrate
103 Anode
105 Hole-Injecting layer (HIL)
107 Hole-Transporting layer (HTL)
108 Exciton-blocking layer (EBL)
109 Light-Emitting layer (LEL)
110 Hole-blocking layer (HBL)
111 Electron-Transporting layer (ETL)
113 Cathode
150 Voltage/Current Source
160 Conductors

1. An electroluminescent device comprising a light-emitting layer containing an organometallic compound comprising a metal and a ligand that coordinates to the metal through at least four bonds as represented by Formula (1) wherein at least one is a carbon-metal bond:
M [symbol] X)ₙ (1)
wherein M represents a metal, X represents an independently selected atom, n≧4, at least one X is carbon, and all X are linked to form a multidentate ligand.

2. An electroluminescent device of claim 1 wherein “n” is 4.

3. An electroluminescent device of claim 1 wherein “n” is greater than 4.

4. The electroluminescent device of claim 2 wherein the metal is selected from group 10 metals.

5. The electroluminescent device of claim 4 wherein the metal is Pt.

6. The electroluminescent device of claim 1 wherein the metal is selected from W, Re, Os, Ru, Rh, Ir, Pd, Pt, Cu, Ag, Au, Pb, and Bi.

7. The electroluminescent device of claim 1 wherein the organometallic compound contains exactly one carbon-metal bond.

8. The electroluminescent device of claim 1 wherein the organometallic compound contains at least two carbon-metal bonds.

9. The electroluminescent device of claim 1 wherein the organometallic compound is represented by Formula (2) to (7) 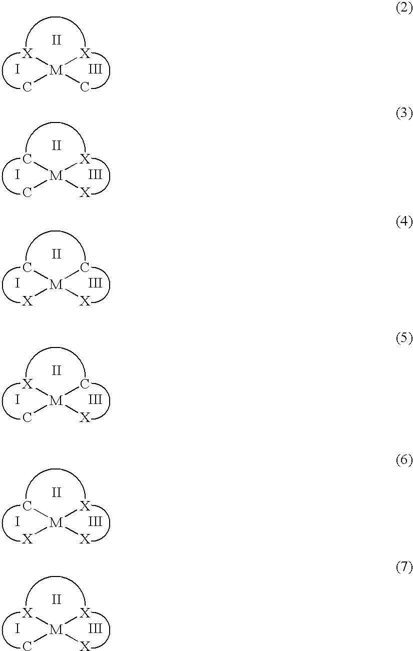
wherein,
M represents a group 10 metal;
C represents a carbon atom;
X independently represents an atom selected from nitrogen, phosphorus, oxygen, and sulfur;
metallacyclic rings I, II, and III are five- or six-membered rings;
C and X can be part of a cyclic structure that can be further substituted, or can be part of an acyclic structure that can be further substituted.

10. The electroluminescent device of claim 1 wherein the organometallic compound is represented by the following Formula (8), (9), (10), or (11): 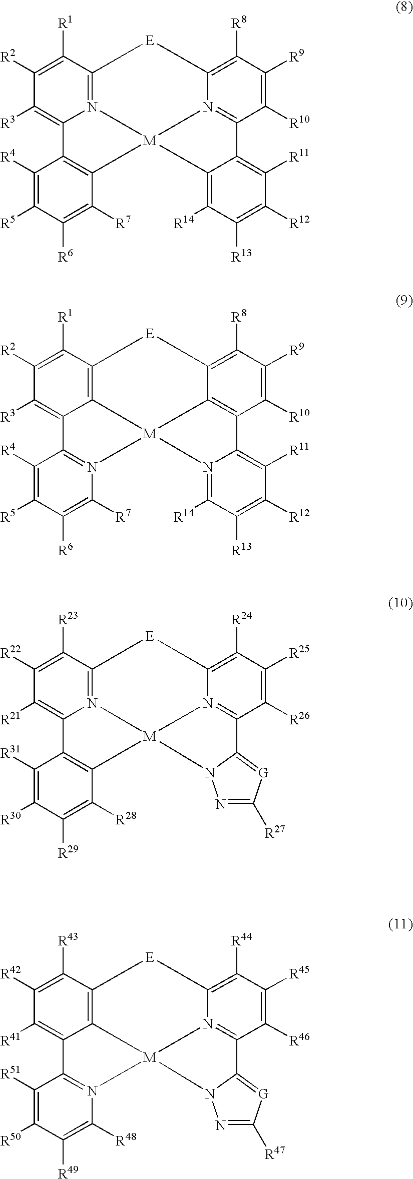
wherein:
M is Pt or Pd;
R¹-R⁷ represent hydrogen or independently selected substituents, provided that R¹ and R², R² and R³, R³ and R⁴, R⁴ and R⁵, R⁵ and R⁶, as well as R⁶ and R⁷ may join to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may join to form a ring group;
R²¹-R³¹ and R⁴¹-R⁵¹ represent hydrogen or independently selected substituents;
G represents nitrogen or carbon; and
E represents a bridging group selected from the following: 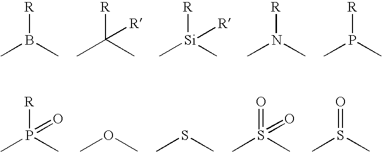
wherein R and R′ represent hydrogen or independently selected substituents;
provided R and R′ may combine to form a ring group.

11. The electroluminescent device of claim 1 wherein the organometallic compound is represented by the following Formula (12): 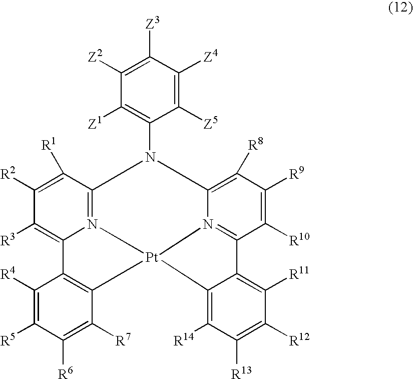
wherein,
R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;
Z¹-Z⁵ represent hydrogen or independently selected substituents, provided that Z¹ and Z², Z² and Z³, Z³ and Z⁴, as well as Z⁴ and Z⁵ may combine to form a ring group.

12. A method for preparation of an organometallic compound that has a structure represented by Formula (8), (9), (10), (11), and (12): 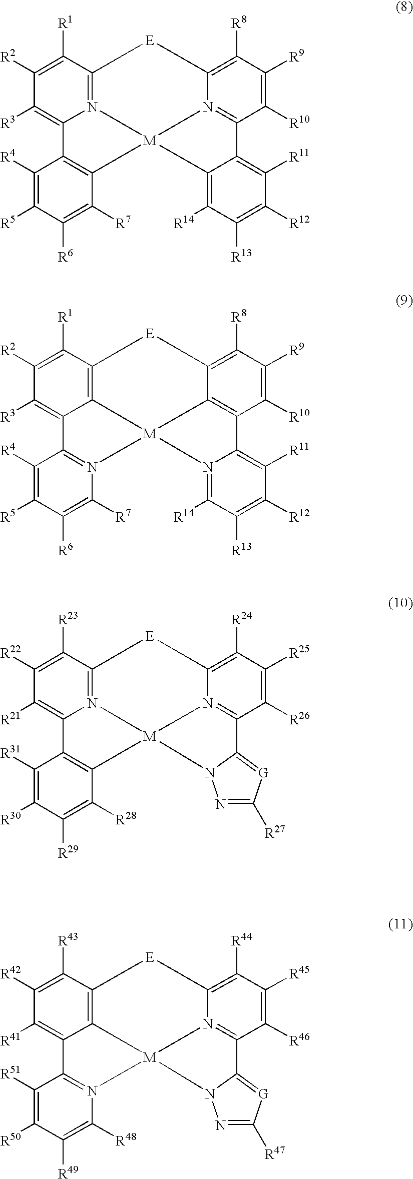
wherein,
M is Pt;
R¹-R⁷ represent hydrogen or independently selected substituents, provided that R¹ and R², R² and R³, R³ and R⁴, R⁴ and R⁵, R⁵ and R⁶, as well as R⁶ and R⁷ may join to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may join to form a ring group;
R²¹-R³¹ and R⁴¹-R⁵¹ represent hydrogen or independently selected substituents;
G represents nitrogen or carbon; and
E represents a bridging group selected from the following: 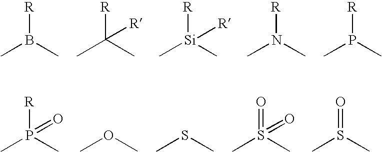
wherein R and R′ represent hydrogen or independently selected substituents;
provided R and R′ may combine to form a ring group comprising a step of reacting, in an organic solvent, a tetradentate cyclometallating ligand with a platinum (II) salt; or 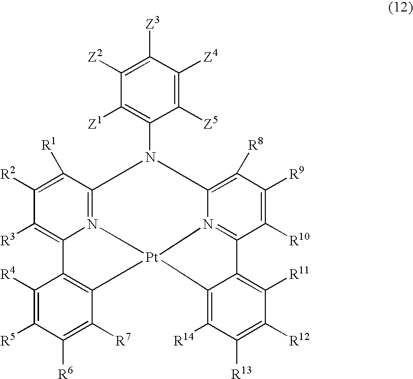
wherein,
R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;
Z¹-Z⁵ represent hydrogen or independently selected substituents, provided that Z¹ and Z², Z² and Z³, Z³ and Z⁴, as well as Z⁴ and Z⁵ may combine to form a ring group,
comprising a step of reacting, in an organic solvent, a tetradentate cyclometallating ligand with a platinum (II) salt.

13. The electroluminescent device of claim 1 wherein the organometallic compound is part of the main chain of a polymer or is part of the side chain of a polymer.

14. The electroluminescent device of claim 1 wherein the organometallic compound is a dopant compound dispersed in a host material.

15. The electroluminescent device of claim 13 wherein the dopant compound is present in an amount of up to 15% wt % based on the host.

16. The electroluminescent device of claim 1 wherein the organometallic compound emits blue, green, or red light.

17. The electroluminescent device of claim 1 that emits white light.

18. The electroluminescent device of claim 17 including a color filter.

19. The electroluminescent device of claim 1 including a fluoresent emitting material.

20. The electroluminescent device of claim 1 wherein the organometallic compound is selected from the following:

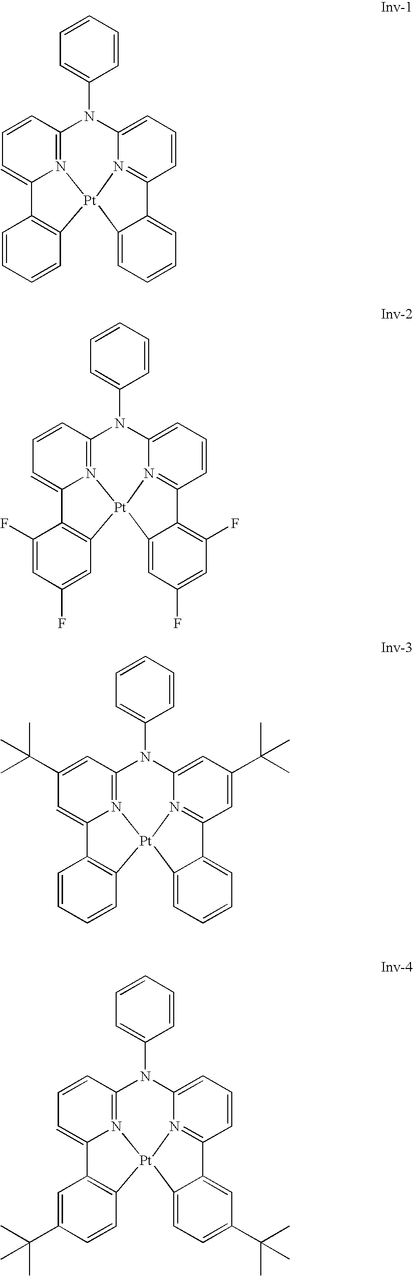

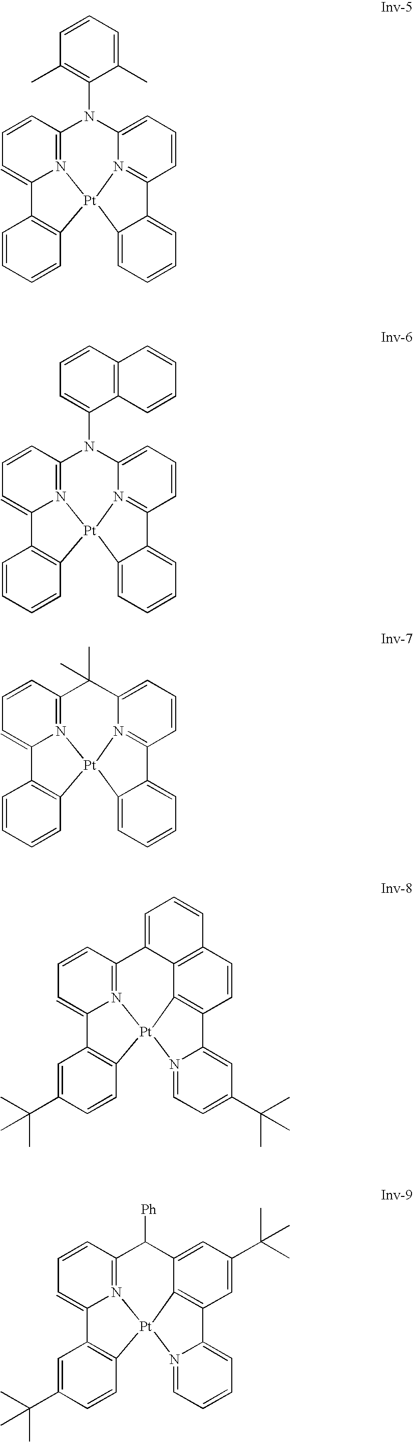

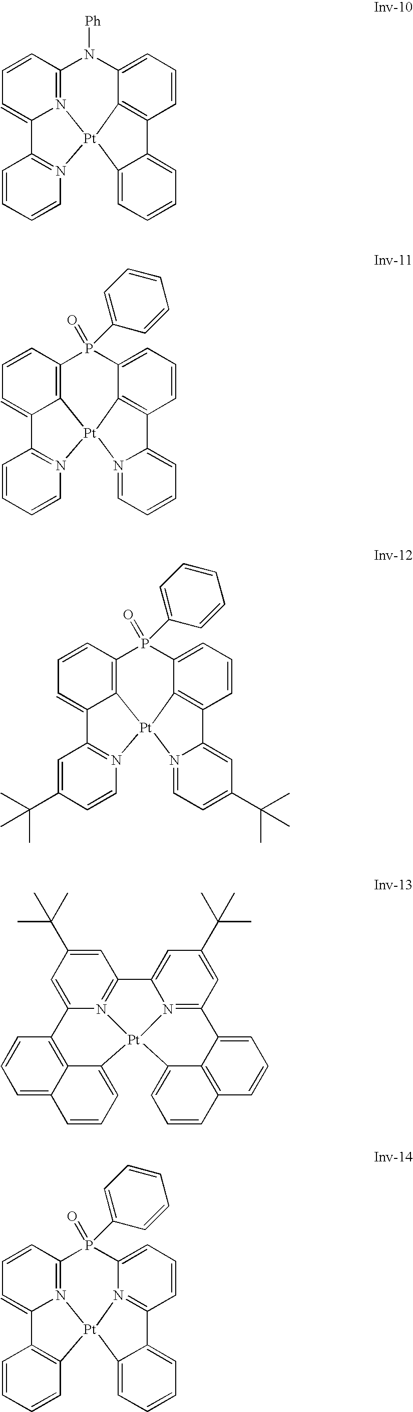

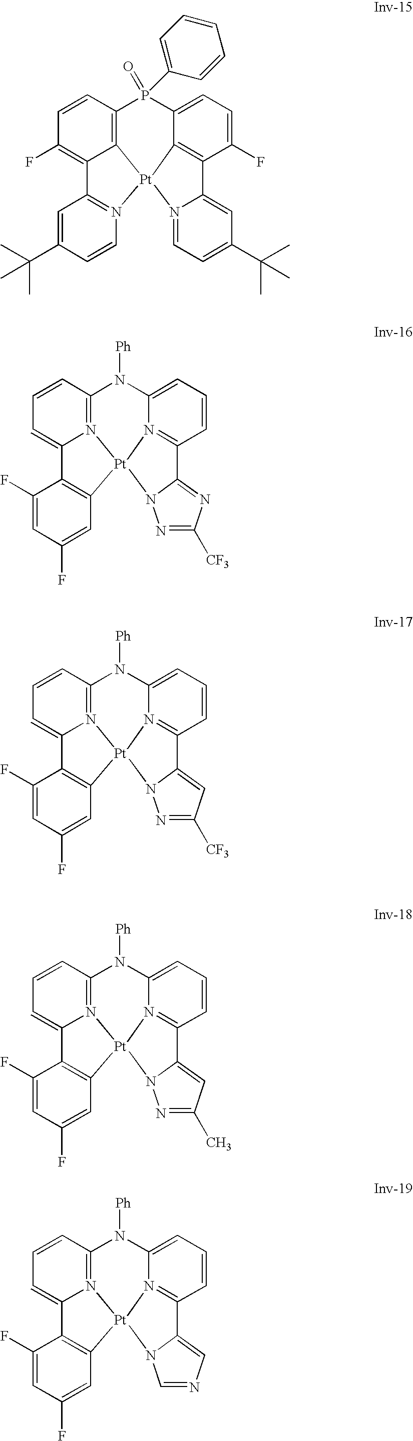

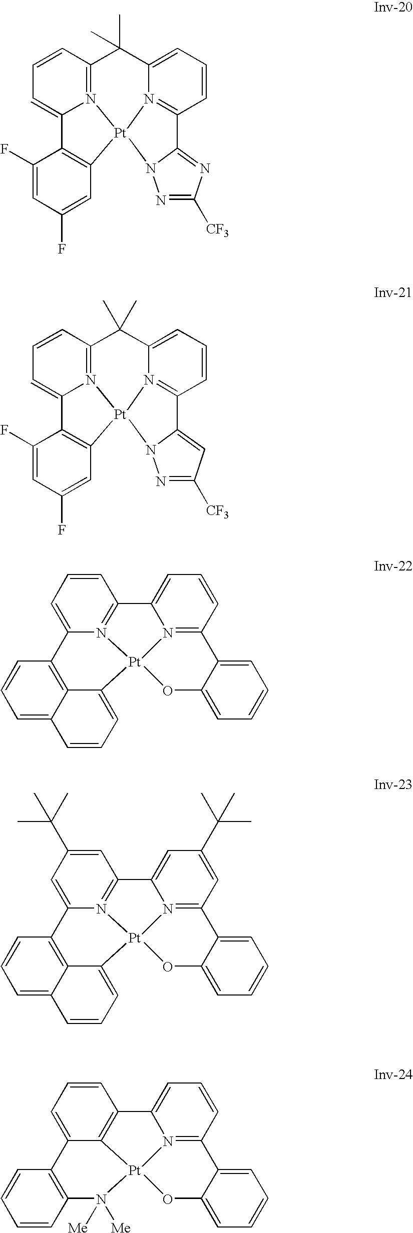

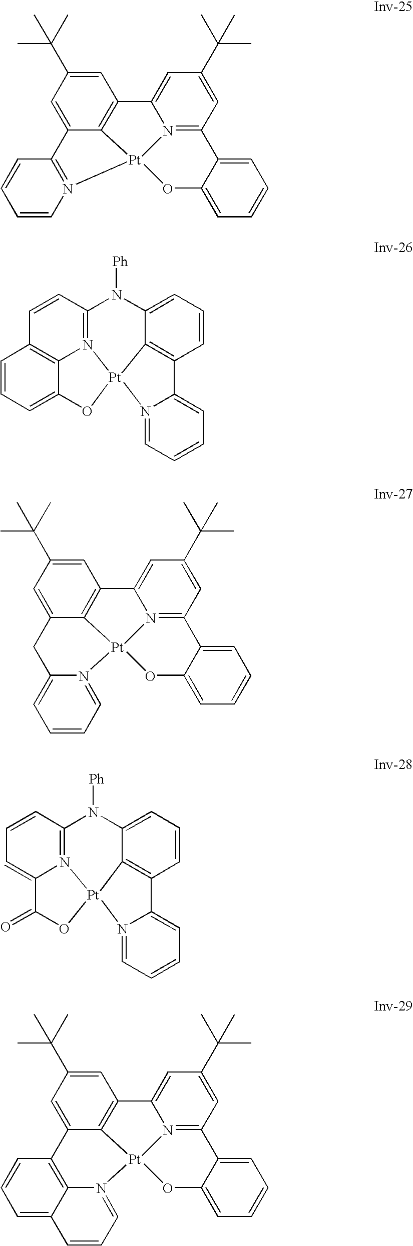

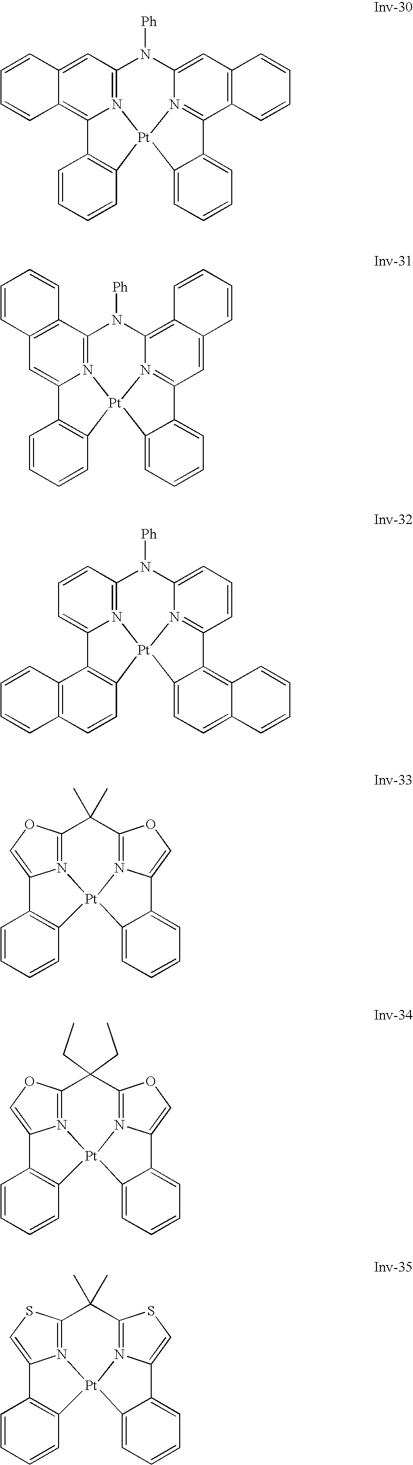

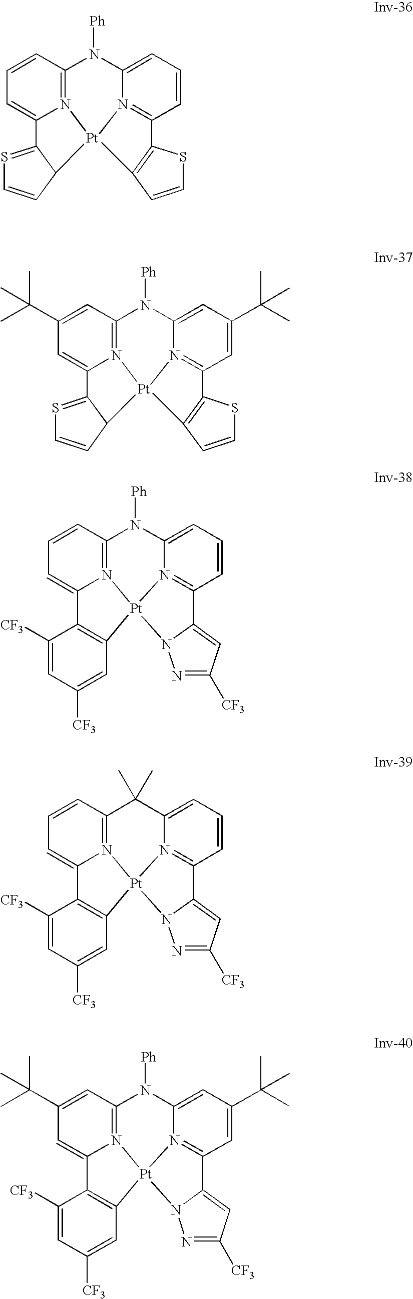

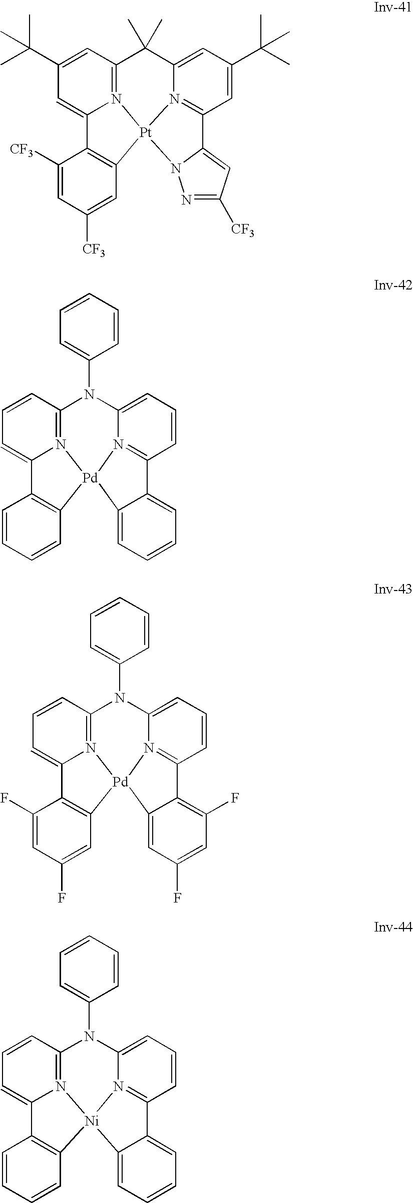

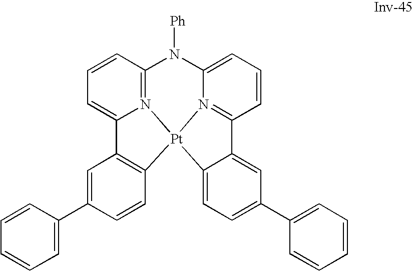

21. The electroluminescent device of claim 14 wherein the host material includes at least one hole transporting co-host and at least one electron transporting co-host, wherein the triplet energy of each of the co-host materials is greater than the triplet energy of the phosphorescent emitter.

22. A device of claim 21 wherein the hole transporting co-host is a triarylamine compound.

23. A device of claim 21 wherein the hole transporting co-host is a carbazole compound.

24. A device of claim 21 wherein the hole transporting co-host is selected from the group consisting of:
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(3-methylphenyl)-N-phenylamino]biphenyl (TPD);
4,4′-Bis-diphenylamino-terphenyl;
2,6,2′,6′-tetramethyl-N,N,N′,N′-tetraphenyl-benzidine;
4,4′,4″-tris[(3-methylphenyl)phenylamino]triphenylamine (MTDATA);
4,4′,4″-tris(N,N-diphenyl-amino) triphenylamine (TDATA);
N,N-bis[2,5-dimethyl-4-[(3-methylphenyl)phenylamino]phenyl]-2,5-dimethyl-N′-(3-methylphenyl)-N′-phenyl-1,4-benzenediamine
1,1-Bis(4-(N,N-di-p-tolylamino)phenyl)cyclohexane (TAPC);
1,1-Bis(4-(N,N-di-p-tolylamino)phenyl)cyclopentane;
4,4′-(9H-fluoren-9-ylidene)bis[N,N-bis(4-methylphenyl)-benzenamine;
1,1-Bis(4-(N,N-di-p-tolylamino)phenyl)-4-phenylcyclohexane;
1,1-Bis(4-(N,N-di-p-tolylamino)phenyl)-4-methylcyclohexane;
1,1-Bis(4-(N,N-di-p-tolylamino)phenyl)-3-phenylpropane;
Bis[4-(N,N-diethylamino)-2-methylphenyl](4-methylpenyl)methane;
Bis[4-(N,N-diethylamino)-2-methylphenyl](4-methylphenyl)ethane;
4-(4-Diethylaminophenyl)triphenylmethane;
4,4′-Bis(4-diethylaminophenyl)diphenylmethane;
4-(9H-carbazol-9-yl)-N,N-bis[4-(9H-carbazol-9-yl)phenyl]-benzenamine (TCTA);
4-(3-phenyl-9H-carbazol-9-yl)-N,N-bis[4(3-phenyl-9H-carbazol-9-yl)phenyl]-benzenamine;
9,9′-[5′-[4-(9H-carbazol-9-yl)phenyl][1,1′:3′,1″-terphenyl]-4,4″-diyl]bis-9H-carbazole;
9,9′-(2,2′-dimethyl[1,1′-biphenyl]-4,4′-diyl)bis-9H-carbazole (CDBP);
9,9′-[1,1′-biphenyl]-4,4′-diylbis-9H-carbazole (CBP);
9,9′-(1,3-phenylene)bis-9H-carbazole (mCP);
9,9′-(1,4-phenylene)bis-9H-carbazole;
9,9′,9″-(1,3,5-benzenetriyl)tris-9H-carbazole;
9,9′-(1,4-phenylene)bis[N,N,N′,N′-tetraphenyl-9H-carbazole-3,6-diamine;
9-[4-(9H-carbazol-9-yl)phenyl]-N,N-diphenyl-9H-carbazol-3-amine;
9,9′-(1,4-phenylene)bis[N,N-diphenyl-9H-carbazol-3-amine; and
9-[4-(9H-carbazol-9-yl)phenyl]-N,N,N′,N′-tetraphenyl-9H-carbazole-3,6-diamine.

25. A device of claim 21 wherein the electron transporting co-host is a benzazole, phenanthroline, 1,3,4-oxadiazole, 1,2,4-triazole, 1,3,5-triazine, triarylborane, or aluminum oxinoid compound.

26. A device of claim 21 wherein the electron transporting co-host is selected from the following: 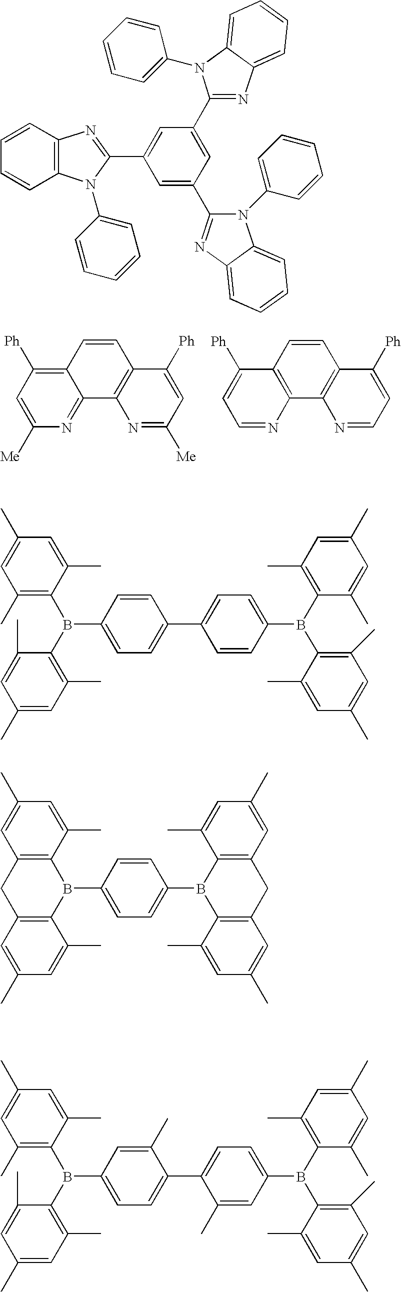 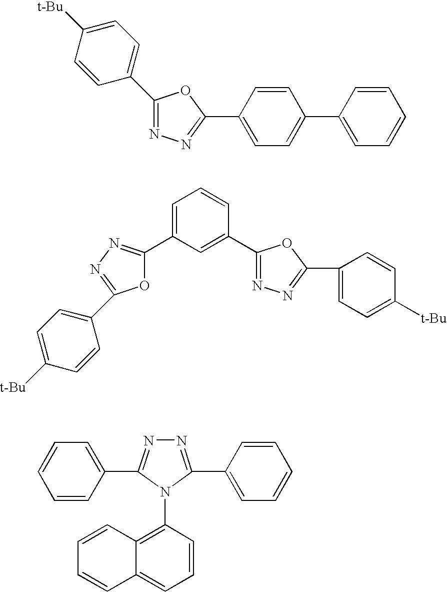
2,4,6-tris(diphenylamino)-1,3,5-triazine;
2,4,6-tricarbazolo-1,3,5-triazine;
2,4,6-tris(N-phenyl-2-naphthylamino)-1,3,5-triazine;
2,4,6-tris(N-phenyl-1-naphthylamino)-1,3,5-triazine;
4,4′,6,6′-tetraphenyl-2,2′-bi-1,3,5-triazine; and
2,4,6-tris([1,1′:3′,1″-terphenyl]-5′-yl)-1,3,5-triazine.

27. A electroluminescent device of claim 1 further containing an electron transporting material, adjacent the light emitting layer on the cathode side, with triplet energy greater than the phosphorescent emitter.

28. The electroluminescent device of claim 1 further containing an exciton blocking layer adjacent the light-emitting layer on the anode side comprising a hole transporting material with triplet energy greater or equal to that of the phosphorescent emitter.

29. A display comprising the OLED device of claim 1.

30. An organometallic compound comprising a metal and a tetradentate cyclometallating ligand that coordinates to the metal through four bonds wherein at least one is a carbon-metal bond.

31. The compound of claim 30 wherein the metal is selected from W, Re, Os, Ru, Rh, Ir, Pd, Pt, Cu, Ag, Au, Pb, and Bi.

32. The compound of claim 30 wherein the organometallic compound contains exactly one carbon-metal bond.

33. The compound of claim 30 wherein the organometallic compound contains at least two carbon-metal bonds.

34. The compound of claim 30 wherein the organometallic compound is represented by Formula (2) to (7) 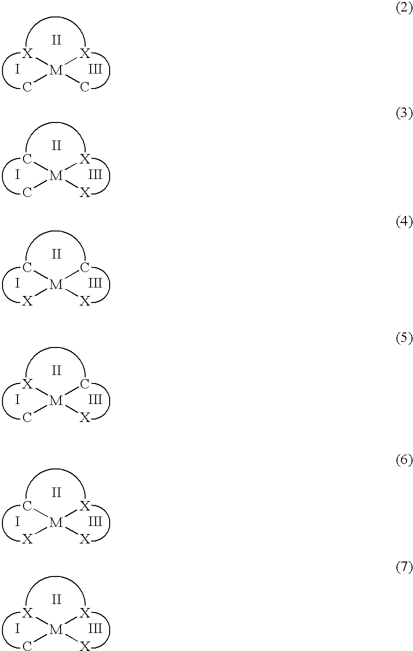
wherein,
M represents a group 10 metal;
C represents a carbon atom;
X independently represents an atom selected from nitrogen, phosphorus, oxygen, and sulfur;
metallacyclic rings I, II, and III are five- or six-membered rings;
C and X can be part of a cyclic structure that can be further substituted, or can be part of an acyclic structure that can be further substituted.

35. The compound of claim 30 wherein the organometallic compound is represented by the following Formula (8), (9), (10), or (11): 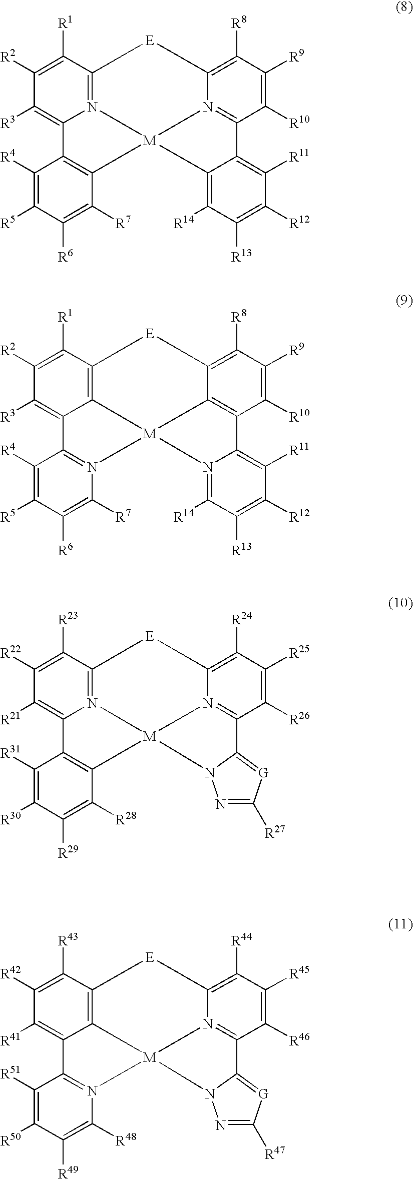
wherein:
M is Pt or Pd;
R¹-R⁷ represent hydrogen or independently selected substituents, provided that R¹ and R², R² and R³, R³ and R⁴, R⁴ and R⁵, R⁵ and R⁶, as well as R⁶ and R⁷ may join to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may join to form a ring group;
R²¹-R³¹ and R⁴¹-R⁵¹ represent hydrogen or independently selected substituents;
G represents nitrogen or carbon; and
E represents a bridging group selected from the following: 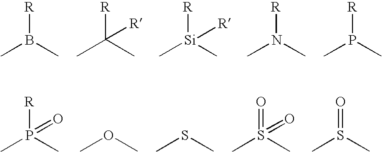
wherein R and R′ represent hydrogen or independently selected substituents;
provided R and R′ may combine to form a ring group.

36. The compound of claim 30 wherein the organometallic compound is represented by the following Formula (12): 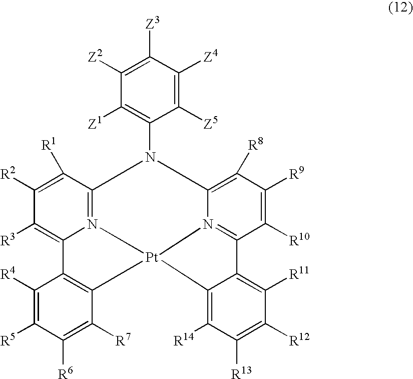
wherein,
R¹-R⁷ represent hydrogen or independently selected substituents, provided that R¹ and R², R² and R³, R³ and R⁴, R⁴ and R⁵, R⁵ and R⁶, as well as R⁶ and R⁷ may combine to form a ring group;
R⁸-R¹⁴ represent hydrogen or independently selected substituents, provided that R⁸ and R⁹, R⁹ and R¹⁰, R¹⁰ and R¹¹, R¹¹ and R¹², R¹² and R¹³, as well as R¹³ and R¹⁴ may combine to form a ring group;
Z¹-Z⁵ represent hydrogen or independently selected substituents, provided that Z¹ and Z², Z² and Z³, Z³ and Z⁴, as well as Z⁴ and Z⁵ may combine to form a ring group.

37. The compound of claim 30 wherein the organometallic compound is selected from the following: 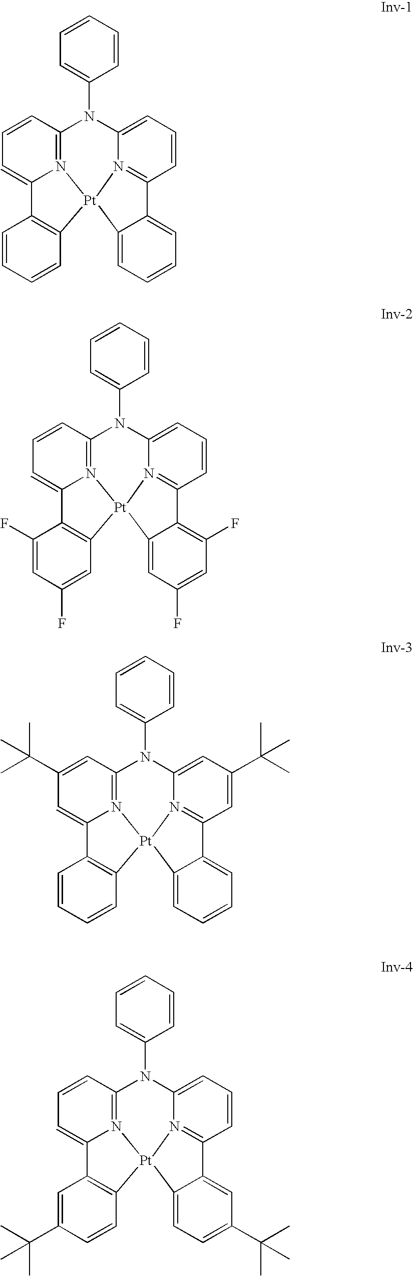 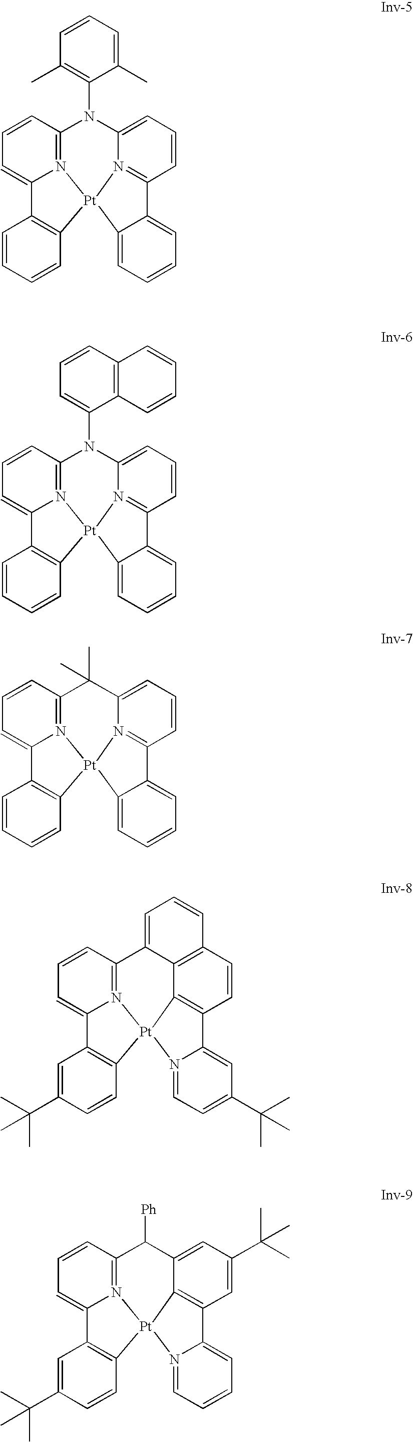 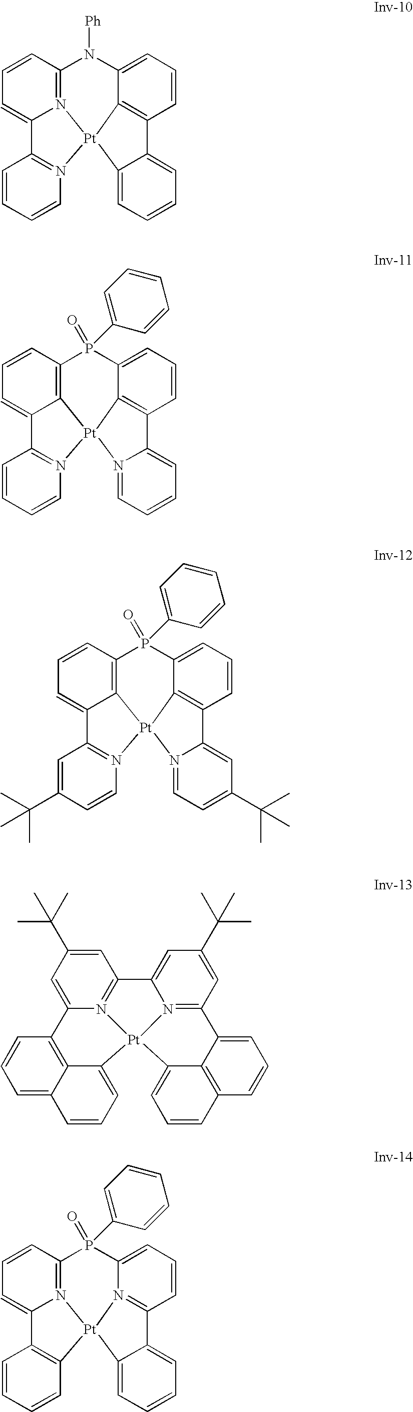 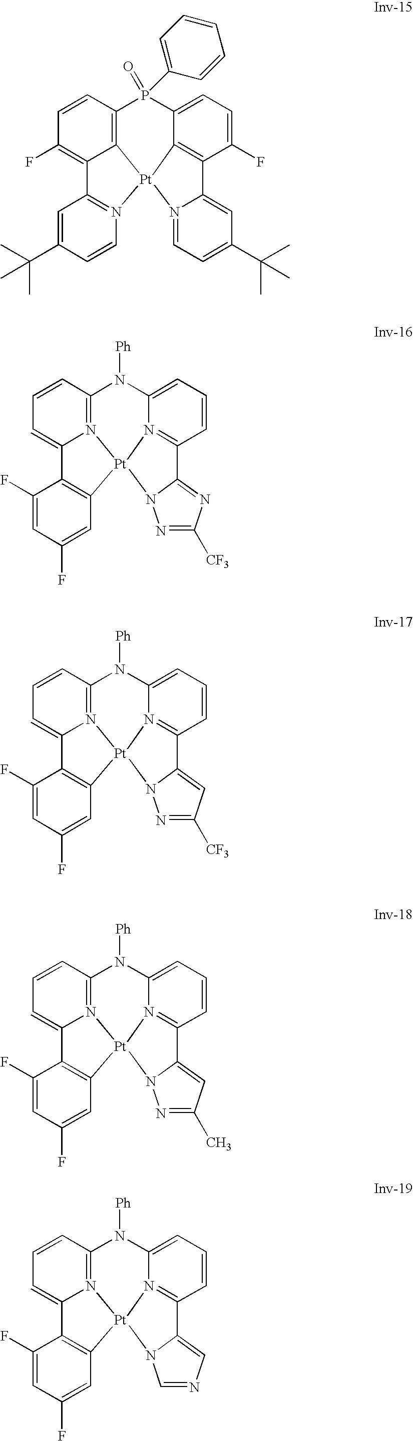 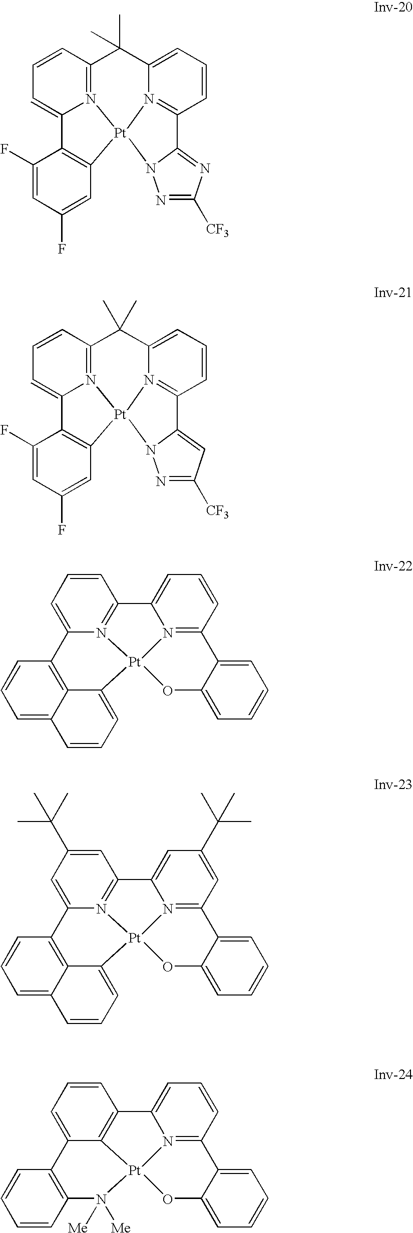 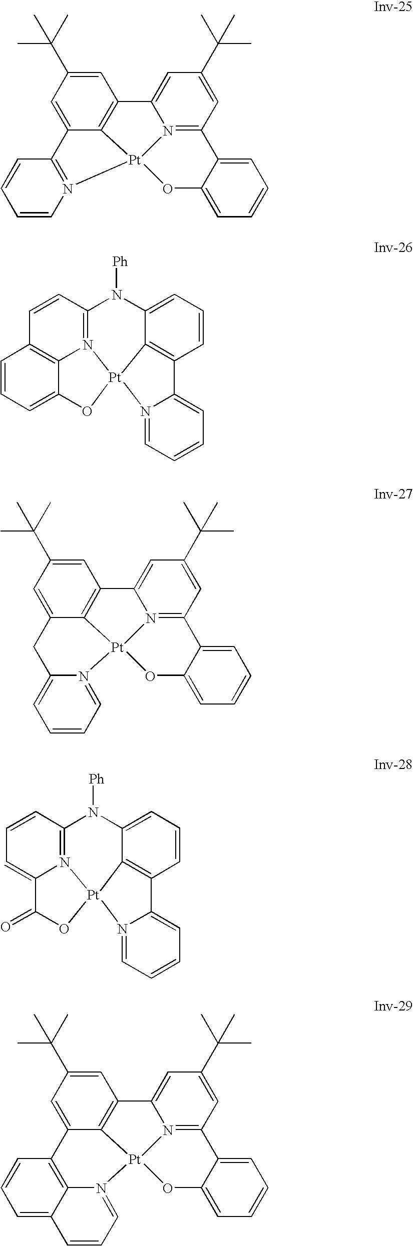 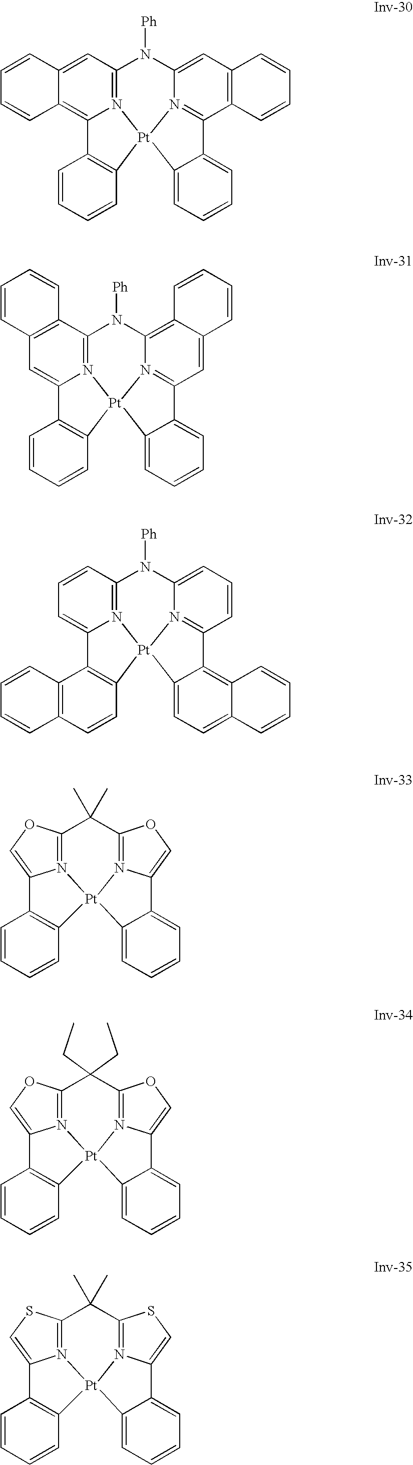 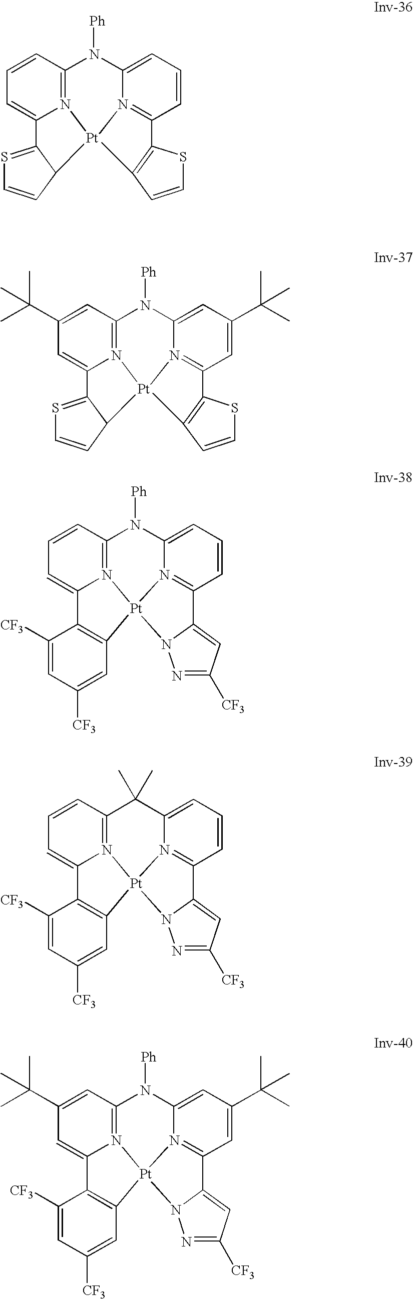 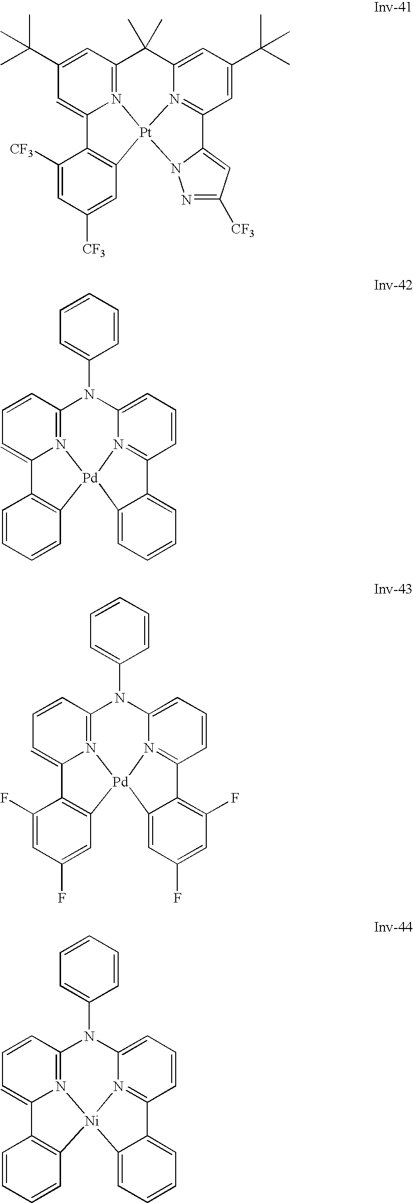 [chemical structure]
